(19) United States
(12) Patent Application Publication
(10) Pub. No.: US 2025/0267856 A1
(43) Pub. Date: Aug. 21, 2025

(54) MICROELECTRONIC DEVICES, AND RELATED METHODS AND MEMORY DEVICES

(71) Applicant: Micron Technology, Inc., Boise, ID (US)

(72) Inventor: Fatma Arzum Simsek-Ege, Boise, ID (US)

(21) Appl. No.: 19/038,549

(22) Filed: Jan. 27, 2025

Related U.S. Application Data
(60) Provisional application No. 63/556,339, filed on Feb. 21, 2024.

(51) Int. Cl. H10B 12/00; H01L 21/762; H01L 23/00; H01L 25/16; H10B 80/00; H10D 80/30

(52) U.S. Cl. CPC H10B 12/50; H01L 21/76224; H01L 24/08; H01L 24/80; H01L 25/16; H10B 12/05; H10B 12/315; H10B 12/488; H10B 80/00; H10D 80/30; H01L 2224/08145; H01L 2224/80895; H01L 2224/80896; H01L 2924/14361; H10B 12/482

(57) ABSTRACT

A microelectronic device includes a memory array structure, an additional memory array structure over and attached to the memory array structure, and a control circuitry structure over and attached to the additional memory array structure. The memory array structure includes an array region having memory cells. The additional memory array structure includes an additional array region having additional memory cells. The additional array region horizontally overlaps the array region. The control circuitry structure includes a control circuitry region horizontally overlapping each of the array region and the additional array region and having control logic devices. The control logic devices are coupled to the memory cells and the additional memory cells. Channels of transistors of the control logic devices are positioned vertically closer to the additional memory cells than are gates of the transistors. Related methods and memory devices are also described.

### CROSS-REFERENCE TO RELATED APPLICATION

This application claims the benefit under 35 U.S.C. § 119 (e) of U.S. Provisional Patent Application Ser. No. 63/556,339, filed Feb. 21, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices, and to related memory devices, electronic systems, and methods.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified, easier and less expensive to fabricate designs.

One example of a microelectronic device is a memory device. Memory devices are generally provided as internal integrated circuits in computers or other electronic devices. There are many types of memory devices including, but not limited to, volatile memory devices. One type of volatile memory device is a dynamic random-access memory (DRAM) device. A DRAM device may include a memory array including DRAM cells arranged rows extending in a first horizontal direction and columns extending in a second horizontal direction. In one design configuration, an individual DRAM cell includes an access device (e.g., a transistor) and a storage node device (e.g., a capacitor) electrically connected to the access device. The DRAM cells of a DRAM device are electrically accessible through digit lines and word lines arranged along the rows and columns of the memory array and in electrical communication with control logic devices within a base control logic structure of the DRAM device.

Control logic devices within a base control logic structure underlying a memory array of a DRAM device have been used to control operations on the DRAM cells of the DRAM device. Control logic devices of the base control logic structure can be provided in electrical communication with digit lines and word lines coupled to the DRAM cells by way of routing and contact structures. Unfortunately, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of a memory device, and/or improvements in the performance (e.g., faster memory cell ON/OFF speed, lower threshold switching voltage requirements, faster data transfer rates, lower power consumption) of the DRAM device.

### BRIEF DESCRIPTION OF THE DRAWINGS

FIG. 1A is a simplified, partial plan view of a memory array structure at a processing stage of a method of forming a microelectronic device, in accordance with embodiments of the disclosure. FIG. 1B is a diagram showing different vertical cross-sectional views of the memory array structure shown in FIG. 1A, taken about lines A-A and B-B of FIG. 1A. FIG. 1C is a simplified, partial plan view of a portion of the memory array structure of FIGS. 1A and 1B showing a “socket out-of-array” layout of digit line contact structures.

FIG. 2A is a simplified, partial plan view of an additional memory array structure at a processing stage of the method of forming a microelectronic device, in accordance with embodiments of the disclosure. FIG. 2B is a diagram showing different vertical cross-sectional views of the memory array structure shown in FIG. 2A, taken about lines A′-A′ and B′-B′ of FIG. 2A.

FIG. 3A is a simplified, partial plan view of a first assembly formed from the memory array structure of FIGS. 1A and 1B and the additional memory array structure of FIGS. 2A and 2B at a processing stage of the method of forming a microelectronic device following the processing stage of FIGS. 1A and 1B and the processing stage of FIGS. 2A and 2B, in accordance with embodiments of the disclosure. FIG. 3B is a diagram showing different vertical cross-sectional views of the first assembly shown in FIG. 3A at the processing stage of FIG. 3A. FIG. 3C is a diagram showing different vertical cross-sectional views of the first assembly at a processing stage following that of FIG. 3B.

FIG. 4A is a simplified partial plan view of a control circuitry structure at a processing stage of the method of forming a microelectronic device, in accordance with embodiments of the disclosure. FIG. 4B is a diagram showing different vertical cross-sectional views of the control circuitry structure shown in FIG. 4A, taken about lines A″-A″ and B″-B″ of FIG. 4A. FIG. 4C is a diagram showing different vertical cross-sectional views of a second assembly formed to include the control circuitry structure shown in FIG. 4B at a processing stage of the method of forming a microelectronic device following the processing stage of FIG. 4B.

FIG. 4D is a diagram showing different vertical cross-sectional views of the second assembly at a processing stage following that of FIG. 4C.

FIG. 5A is a simplified, partial plan view of a third assembly formed from the first assembly of FIG. 3C and the second assembly of FIG. 4D at a processing stage of the method of forming a microelectronic device following the processing stage of FIG. 3C and the processing stage of FIG. 4D, in accordance with embodiments of the disclosure. FIG. 5B is a diagram showing different vertical cross-sectional views of the third assembly shown in FIG. 5A at the processing stage of FIG. 5A.

FIG. 6 is a diagram showing different vertical cross-sectional views of a microelectronic device at a processing stage of the method of forming a microelectronic device following the processing stage of FIGS. 5A and 5B, in accordance with embodiments of the disclosure.

FIG. 7 is a schematic block diagram of an electronic system, in accordance with an embodiment of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory; conventional non-volatile memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for case of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10-8 Siemens per centimeter (S/cm) and about 104 S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}AS_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON₂), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn₂O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓ N_{y}, SiOₓC_{y}, SiCₓO_{y}H₂, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

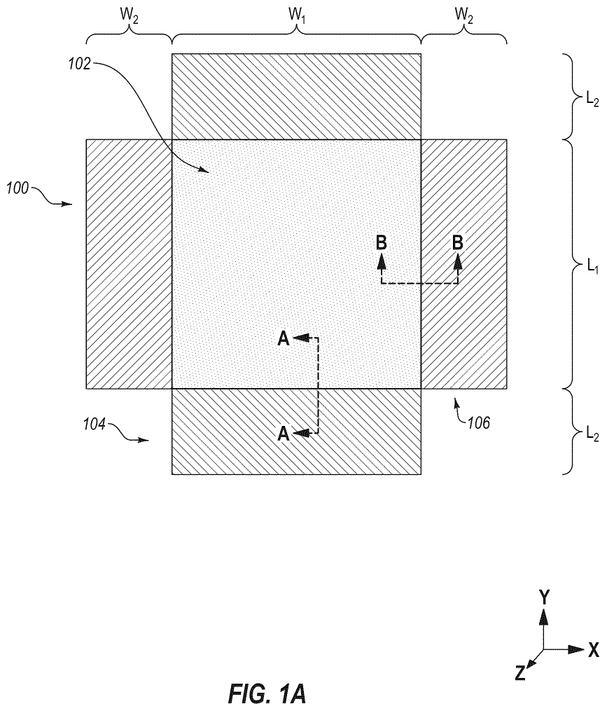

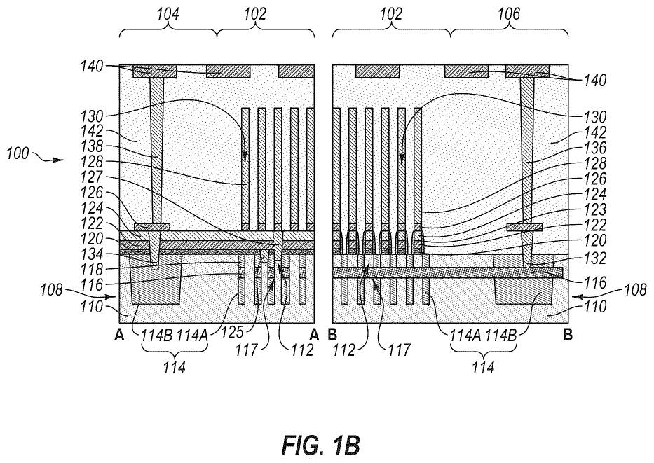

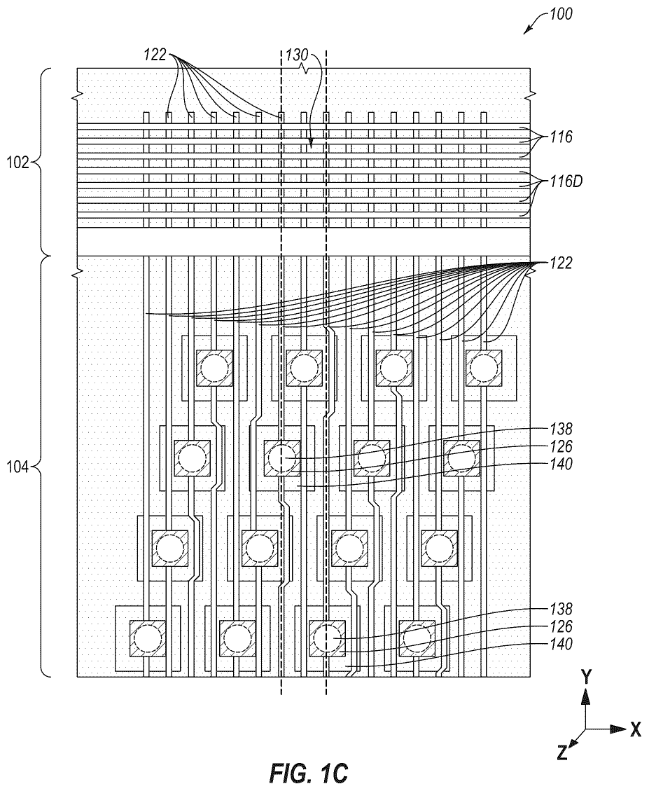

FIGS. 1A through 6 are various views (described in further detail below) illustrating different processing stages of a method of forming a microelectronic device (e.g., a memory device, such as a DRAM device), in accordance with embodiments of the disclosure. With the description provided below, it will be readily apparent to one of ordinary skill in the art that the methods and structures described herein may be used to form various devices and electronic systems.

FIG. 1A shows a simplified, partial plan view of a memory array structure 100 (e.g., a first wafer, a first die) at an early processing stage of a method of forming a microelectronic device (e.g., a memory device, such as a DRAM device), in accordance with embodiments of the disclosure. As shown in FIG. 1A, the memory array structure 100 may be formed to include an array region 102, digit line (DL) exit regions 104 (also referred to as “digit line (DL) contact socket regions”) horizontally neighboring the array region 102 in a Y-direction (e.g., a first horizontal direction), and word line (WL) exit regions 106 (also referred to as “word line (WL) contact socket regions”) horizontally neighboring the array region 102 in an X-direction (e.g., a second horizontal direction) orthogonal to the Y-direction. The array region 102, the DL exit regions 104, and the WL exit regions 106 are each described in further detail below. FIG. 1B is a diagram showing different vertical cross-sectional views of the memory array structure 100 shown in FIG. 1A, taken about lines A-A and B-B of FIG. 1A. The vertical cross-section of the memory array structure 100 taken about line A-A is a view of a YZ-plane of a portion of the memory array structure 100 horizontally overlapping the array region 102 and one of the DL exit regions 104 of the memory array structure 100. The vertical cross-section of the memory array structure 100 taken about line B-B is a view of an XZ-plane of an additional portion of the memory array structure 100 overlapping the array region 102 and one of the WL exit regions 106 of the memory array structure 100.

Referring to FIG. 1A, the array region 102 of the memory array structure 100 is a horizontal area of the memory array structure 100 configured to have an array of memory cells (e.g., an array of DRAM cells) therein, as described in further detail below. The memory array structure 100 may include a desired quantity and distribution of array regions 102. For clarity and ease of understanding of the drawings and related description, FIG. 1A depicts the memory array structure 100 as including one (1) array region 102, but the memory array structure 100 may be formed to include multiple (e.g., more than one (1)) array regions 102 horizontally offset (e.g., in one or more of the X-direction and the Y-direction) from one another. For example, the memory array structure 100 may include greater than or equal to four (4) array regions 102, greater than or equal to eight (8) array regions 102, greater than or equal to sixteen (16) array regions 102, greater than or equal to thirty-two (32) array regions 102, greater than or equal to sixty-four (64) array regions 102, greater than or equal to one hundred twenty-eight (128) array regions 102, greater than or equal to two hundred fifty-six (256) array regions 102, greater than or equal to five hundred twelve (512) array regions 102, or greater than or equal to one thousand twenty-four (1024) array regions 102.

As shown in FIG. 1A, the array region 102 of the memory array structure 100 may have a first width W₁ in the X-direction and a first length L₁ in the Y-direction orthogonal to the X-direction. In some embodiments, the first width W₁ is substantially equal to the first length L₁. In additional embodiments, the first width W₁ is different than (e.g., greater than, less than) the first length L₁.

The DL exit regions 104 of the memory array structure 100 may include horizontal areas of the memory array structure 100 configured include portions of DL structures (e.g., bit line structures, data line structures) within horizontal boundaries thereof. For an individual DL exit region 104, at least some DL structures operatively associated with the array region 102 horizontally neighboring the DL exit region 104 in the Y-direction may have portions within the horizontal area of the DL exit region 104. In addition, the DL exit regions 104 may also be configured to include conductive contact structures and conductive routing structures within the horizontal areas thereof that are operatively associated with the DL structures. As described in further detail below, some of the conductive contact structures within the DL exit regions 104 may couple the DL structures to control logic circuitry of control logic devices (e.g., sense amplifier (SA) devices) to subsequently be provided vertically over the memory array structure 100. In some embodiments, the DL exit regions 104 respectively horizontally extend in the X-direction. An individual array region 102 may be horizontally interposed between horizontally neighboring DL exit regions 104 in the Y-direction.

As shown in FIG. 1A, the DL exit regions 104 of the memory array structure 100 may respectively have the first width W₁ in the X-direction and a second length L₂ in the Y-direction orthogonal to the X-direction. The second length L₂ of an individual DL exit region 104 is smaller than the first width W₁ of the DL exit region 104. In addition, the second length L₂ of the DL exit region 104 is smaller than the first length L₁ of an individual array region 102 of the memory array structure 100.

The WL exit regions 106 of the memory array structure 100 may include additional horizontal areas of the memory array structure 100 configured include portions of WL structures (e.g., access line structures) within horizontal boundaries thereof. For an individual WL exit region 106, at least some WL structures operatively associated with the array region 102 horizontally neighboring the WL exit region 106 in the X-direction may have portions within the horizontal area of the WL exit region 106. In addition, the WL exit regions 106 may also be configured to include additional conductive contact structures and additional conductive routing structures within the horizontal areas thereof that are operatively associated with the WL structures. As described in further detail below, some of the additional conductive contact structures within the WL exit regions 106 may couple the WL structures to additional control logic circuitry of additional control logic devices (e.g., sub word line driver (SWD) devices) to subsequently be provided vertically over the memory array structure 100. In some embodiments, the WL exit regions 106 respectively horizontally extend in the Y-direction. An individual array region 102 may be horizontally interposed between horizontally neighboring WL exit regions 106 in the X-direction.

As shown in FIG. 1A, the WL exit regions 106 of the memory array structure 100 may respectively have a second width W₂ in the X-direction and the first length L₁ in the Y-direction orthogonal to the X-direction. The second width W₂ of an individual WL exit region 106 is smaller than the first length L₁ of the WL exit region 106. In addition, the second width W₂ of the WL exit region 106 is smaller than the first width W₁ of an individual array region 102 of the memory array structure 100.

Referring next to FIG. 1B, the memory array structure 100 may be formed to include a base structure 108 including semiconductor material 110 and isolation structures 114 (e.g., shallow trench isolation (STI) structures) vertically extending into the semiconductor material 110. The isolation structures 114 may define boundaries of active regions 112 of the semiconductor material 110, as described in further detail below.

The base structure 108 comprises a base material or construction upon which additional features (e.g., materials, structures, devices) of the memory array structure 100 are formed. The base structure 108 may comprise a semiconductor structure (e.g., a semiconductor wafer), or a base semiconductor material on a supporting structure. For example, the base structure 108 may comprise a conventional silicon substrate (e.g., a conventional silicon wafer), or another bulk substrate comprising a semiconductor material. In some embodiments, the base structure 108 comprises a silicon wafer. The base structure 108 may include one or more layers, structures, and/or regions formed therein and/or thereon.

The isolation structures 114 of the memory array structure 100 may include trenches (e.g., openings, vias, apertures) within the semiconductor material 110 of base structure 108 filled with insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC₂N_{y}), and amorphous carbon. In some embodiments, the isolation structures 114 are respectively formed of and include SiOₓ (e.g., SiO₂).

The isolation structures 114 may include first isolation structures 114A and second isolation structures 114B. The first isolation structures 114A may have one or more different geometric configuration(s) (e.g., different dimension(s), different shape(s)) and different horizontal positioning relative to the second isolation structures 114B. As shown in FIG. 1B, in some embodiments, the first isolation structures 114A are respectively positioned within a horizontal area of the array region 102 of the memory array structure 100; and the second isolation structures 114B are respectively positioned within a horizontal area of one of the DL exit regions 104 or one of the WL exit regions 106 of the memory array structure 100. In addition, at least some of the first isolation structures 114A may respectively have different horizontal dimension(s) than at least some of the second isolation structures 114B. At least some of the isolation structures 114 (e.g., at least some of the first isolation structures 114A and/or at least some of the second isolation structures 114B) vertically extend to and terminate at a different vertical position than some other of the isolation structures 114 (e.g., at least some other of the first isolation structures 114A and/or at least some other of the second isolation structures 114B). For example, some of the isolation structures 114 may be formed to be relatively vertically shallower than some other of the isolation structures 114. Some of the isolation structures 114 may be employed as shallow trench isolation (STI) structures within the base structure 108.

Within the array region 102 of the memory array structure 100, some of the isolation structures 114 (e.g., some of the first isolation structures 114A) may at least partially define boundaries of the active regions 112 of the semiconductor material 110 of the base structure 108. The active regions 112 of the semiconductor material 110 may individually vertically extend (e.g., project) from a relatively lower portion of the semiconductor material 110 that horizontally extends across and between the active regions 112. The active regions 112 may be considered pillar structures of the semiconductor material 110.

The active regions 112 of the semiconductor material 110 may individually exhibit an elongate (e.g., non-circular, non-square) horizontal cross-sectional shape at least partially defined by the horizontal cross-sectional shapes of the first isolation structures 114A horizontally adjacent thereto. The active regions 112 may individually include an upper surface, opposing horizontal ends, and opposing horizontal sides extending from and between the opposing ends. Intersections of the opposing horizontal ends of an individual active region 112 with the opposing horizontal sides of the active region 112 may define horizontal corners of the active region 112. As shown in FIG. 1B, the upper surfaces of the active regions 112 may be substantially coplanar with one another. In addition, an individual active region 112 may include a DL contact region (e.g., bit line contact region) and storage node contact regions (e.g., cell contact regions). The storage node contact regions of the active region 112 may be located proximate the opposing horizontal ends of the active region 112, and the DL contact region may be horizontally interposed between the storage node contact regions. The DL contact region may be positioned at or proximate to a horizontal center of the active region 112. In some embodiments, the DL contact region of an individual active region 112 is horizontally narrower (e.g., in the X-direction shown in FIG. 1A) than each of the storage node contact regions of the active region 112. The DL contact region and the storage node contact regions of an individual active region 112 may be separated from one another by a pair of the first isolation structures 114A.

With continued reference to FIG. 1B, WL structures 116 may be at least partially embedded within the isolation structures 114 and may horizontally extend in parallel in the X-direction (FIG. 1A) completely through the array region 102 and at least partially through the WL exit region 106. At least some of the WL structures 116 may terminate within the WL exit region 106. In the portion of FIG. 1B showing a vertical cross-section of the memory array structure 100 about line B-B, the illustrated WL structure 116 is depicted by way of dashed lines to represent that it is outside of (e.g., horizontally offset in the Y-direction (FIG. 1A) from) the vertical plane (e.g., XZ-plane) of line B-B. As shown in FIG. 1B, tops (e.g., upper vertically boundaries) of the WL structures 116 may be substantially coplanar with one another. Side surfaces and a bottom surface of an individual WL structure 116 may be covered by insulative material of a respective one of the isolation structures 114. For example, portions of the isolation structure 114 may be horizontally interposed between the WL structure 116 and a respective active region 112 of the semiconductor material 110 of the base structure 108. The WL structures 116 may individually be formed of and include conductive material. In some embodiments, the WL structures 116 are individually formed of and include one or more of W, Ru, Mo, and TiN_{y}.

Within the array region 102, the memory array structure 100 further includes access devices 117. The access devices 117 may individually include a channel region comprising a portion of an active region 112 of the semiconductor material 110 of the base structure 108; a source region and a drain region respectively horizontally neighboring the channel region and individually comprising a conductively doped portion of the active region 112 of the semiconductor material 110 of the base structure 108; at least one gate structure comprising a portion of at least one of the WL structures 116; and a gate dielectric structure comprising a portion of the insulative material of the first isolation structure 114A interposed between the channel region thereof and the gate structure thereof.

Still referring to FIG. 1B, WL capping structures 118 may be formed on or over the WL structures 116. The WL capping structures 118 may at least partially (e.g., substantially) cover upper surfaces of the WL structures 116 and may horizontally neighbor the active regions 112 of the semiconductor material 110 of the base structure 108. The WL capping structures 118 may individually be formed of and include at least one insulative material. In some embodiments, the WL capping structures 118 are individually formed of and include dielectric nitride material (e.g., SiN_{y}, such as Si₃N₄).

The memory array structure 100 may further include a first dielectric material 120 on or over the base structure 108. Within the array region 102, the first dielectric material 120 may overlie the access devices 117. The first dielectric material 120 may individually be formed of and include insulative material. In some embodiments, the first dielectric material 120 is formed of and includes dielectric oxide material (e.g., SiOₓ, such as SiO₂).

With continued reference to FIG. 1B, DL structures 122 may vertically overlie the first dielectric material 120 and may horizontally extend in parallel in the Y-direction (FIG. 1A) completely through the array region 102 and at least partially through the DL exit region 104. At least some of the DL structures 122 may terminate within the DL exit region 104. As shown in FIG. 1B, tops (e.g., upper vertical boundaries) of the DL structures 122 may be substantially coplanar with one another. The DL structures 122 may individually be formed of and include conductive material. In some embodiments, the DL structures 122 are individually formed of and include one or more of W, Ru, Mo, and TiN_{y}.

Still referring to FIG. 1B, DL capping structures 124 may be formed on or over upper surfaces of the DL structures 122, and DL spacer structures 123 may be formed on or over side surfaces (e.g., sidewalls) of the DL structures 122. The DL capping structures 124 may at least partially (e.g., substantially) cover the upper surfaces of the DL structures 122, and the DL spacer structures 123 may at least partially (e.g., substantially) cover the side surfaces of the DL structures 122. As shown in FIG. 1B, in some embodiments, upper boundaries of the DL spacer structures 123 vertically overlie the upper surfaces of the DL structures 122, and lower boundaries of the DL spacer structures 123 vertically underlie lower surfaces of the DL structures 122. The DL capping structures 124 and the DL spacer structures 123 may individually be formed of and include at least one insulative material. In some embodiments, the DL capping structures 124 and the DL spacer structures 123 are individually formed of, and include one or more of, dielectric oxide material (e.g., SiOₓ, such as SiO₂) and dielectric nitride material (e.g., SiN_{y}, such as Si₃N₄).

Within the array region 102, the memory array structure 100 may further include first DL contact structures 125 (also referred to herein as “DIGITCON” structures) vertically overlying and in contact with the active regions 112 of the semiconductor material 110 of the base structure 108. The first DL contact structures 125 may vertically extend through the first dielectric material 120 and into the active regions 112 of the semiconductor material 110 of the base structure 108. The first DL contact structures 125 horizontally overlap (e.g., in the X-direction and the Y-direction shown in FIG. 1A) DL contact sections of the active regions 112. The first DL contact structures 125 may respectively vertically extend from a DL contact section of an individual active region 112, through the first dielectric material 120, and to an individual DL structure 122. An individual first DL contact structure 125 may be horizontally interposed between two (2) of the WL structures 116 (and, hence, two (2) of the isolation structures 114) neighboring one another in the Y-direction (FIG. 1A), and may be horizontally interposed between two (2) of storage node contact sections of an individual active region 112 in an additional horizontal direction angled relative to the Y-direction (FIG. 1A) and the X-direction (FIG. 1A). An individual first DL contact structure 125 may be coupled to one of the source/drain regions (e.g., the source region) of an individual access device 117 of the memory array structure 100. Within the horizontal area of an individual active region 112, an individual first DL contact structure 125 may be coupled to two (2) (e.g., a pair) of the access devices 117 operatively associated with the active region 112. For example, the two (2) of the access devices 117 may share a source region within the active region 112 with one another, and the first DL contact structure 125 may be coupled to the shared source region of the two (2) of the access devices 117. The first DL contact structures 125 may individually be formed of and include conductive material.

Within the array region 102, the memory array structure 100 may further include storage node contact structures 127 (also referred to herein as “CELLCON” structures) vertically overlying and in contact with the active regions 112 of the semiconductor material 110 of the base structure 108. The storage node contact structures 127 may vertically extend through the first dielectric material 120 and into the active regions 112 of the semiconductor material 110 of the base structure 108. The storage node contact structures 127 horizontally overlap (e.g., in the X-direction and the Y-direction shown in FIG. 1A) storage node contact sections of the active regions 112. In the portion of FIG. 1B showing a vertical cross-section of the memory array structure 100 about line A-A, the illustrated storage node contact structure 127 is depicted by way of dashed lines to represent that it is outside of (e.g., horizontally offset in the X-direction (FIG. 1A) from) the vertical plane (e.g., YZ-plane) of line A-A. The storage node contact structures 127 may respectively vertically extend from a storage node contact section of an individual active region 112, through the first dielectric material 120, and to a redistribution material (RDM) structure 126 vertically overlying the DL capping structures 124. An individual storage node contact structure 127 may be horizontally interposed between two (2) of the WL structures 116 (and, hence, two (2) of the isolation structures 114) neighboring one another in the Y-direction (FIG. 1A), and may horizontally neighbor the DL contact section of an individual active region 112 in an additional horizontal direction angled relative to the Y-direction (FIG. 1A) and the X-direction (FIG. 1A). An individual storage node contact structure 127 may be coupled to one of the source/drain regions (e.g., the drain region) of an individual access device 117 of the memory array structure 100. Within the horizontal area of an individual active region 112, an individual storage node contact structure 127 may be coupled to one (1) of two (2) (e.g., a pair) of access devices 117 operatively associated with the active region 112. For example, the two (2) of the access devices 117 have separate drain regions than one another within the active region 112, and the individual storage node contact structure 127 may be coupled to the drain region of one (1) of the two (2) of the access devices 117. An individual active region 112 of the semiconductor material 110 may have two (2) storage node contact structures 127 in contact therewith. The storage node contact structures 127 may individually be formed of and include conductive material.

Still referring to FIG. 1B, a redistribution material (RDM) tier (also referred to as “redistribution layer” (RDL) tier) may be formed to vertically overlie the DL capping structures 124 and may include RDM structures 126 (also referred to as RDL structures). Within the array region 102, at least some of the RDM structures 126 may, for example, be employed to facilitate a horizontal arrangement (e.g., a hexagonal close packed arrangement) of storage node devices 128 that is different than a horizontal arrangement of the storage node contact structures 127, while electrically connecting the storage node contact structures 127 (and, hence, the access devices 117) to the storage node devices 128. In addition, within the DL exit region 104 and the WL exit region 106, at least some other of the RDM structures 126 may vertically extend between and couple vertically neighboring conductive contact structures with the DL exit region 104 and the WL exit region 106, as described in further detail below. The RDM structures 126 may individually be formed of and include conductive material. In some embodiments, the RDM structures 126 are individually formed of and include one or more of W, Ru, Mo, and TiN_{y}.

Within the array region 102, the storage node devices 128 (e.g., capacitors) may be formed on or over the RDM structures 126. The storage node devices 128 may be in electrical contact with the RDM structures 126, and, hence with the storage node contact structures 127, and the access devices 117. The storage node devices 128 may be coupled to the access devices 117 by way of the storage node contact structures 127 and the RDM structures 126 to form memory cells 130 (e.g., DRAM cells) within the array region 102. Each memory cell 130 may individually include one of the access devices 117, one of the storage node devices 128, one of the storage node contact structures 127, and one of the RDM structures 126. The storage node devices 128 may individually be formed and configured to store a charge representative of a programmable logic state of the memory cell 130 including the storage node device 128. In some embodiments, the storage node devices 128 are capacitors. During use and operation, a charged capacitor may represent a first logic state, such as a logic 1; and an uncharged capacitor may represent a second logic state, such as a logic 0. Each of the storage node devices 128 may, for example, be formed to include a first electrode (e.g., a bottom electrode), a second electrode (e.g., a top electrode), and a dielectric material between the first electrode and the second electrode.

At least one conductive routing tier (e.g., at least two conductive routing tiers) including first routing structures 140 may be formed vertically over the memory cells 130. The first routing structures 140 may, for example, include one or more of pad structures and line structures. The first routing structures 140 may respectively be formed of and include conductive material. In some embodiments, the first routing structures 140 are individually formed of and include one or more of W, Ru, Mo, and TiN_{y}.

Within the WL exit regions 106, the memory array structure 100 further includes first WL contact structures 132 and second WL contact structures 136. Within an individual WL exit region 106, the first WL contact structures 132 may vertically extend between and couple some of the RDM structures 126 and some of the WL structures 116; and the second WL contact structures 136 may vertically extend between and couple some of the RDM structures 126 and some of the first routing structures 140 vertically overlying the memory cells 130. The first WL contact structures 132 and second WL contact structures 136 may be considered to be so-called “edge of array” WL contact structures. In the portion of FIG. 1B showing a vertical cross-section of the memory array structure 100 about line B-B, the illustrated first WL contact structure 132 is depicted by way of dashed lines to represent that it is outside of (e.g., horizontally offset in the Y-direction (FIG. 1A) from) the vertical plane (e.g., XZ-plane) of line B-B. An individual first WL contact structure 132 may be formed to have an upper surface in physical contact with one of the RDM structures 126; and a lower surface on, within, or below one of the WL structures 116. In addition, an individual second WL contact structure 136 may be formed to have an upper surface in physical contact with one of the first routing structures 140; and a lower surface on, within, or below one of the RDM structures 126. The first WL contact structures 132 and the second WL contact structures 136 may respectively be formed of and include conductive material. In some embodiments, the first WL contact structures 132 and the second WL contact structures 136 are individually formed of and include one or more of W, Ru, Mo, and TiN_{y}.

Within the DL exit regions 104, the memory array structure 100 further includes second DL contact structures 134 and third DL contact structures 138. Within an individual DL exit region 104, the second DL contact structures 134 may vertically extend between and couple some of the RDM structures 126 and some of the DL structures 122; and the third DL contact structures 138 may vertically extend between and couple some of the RDM structures 126 and some of the first routing structures 140 vertically overlying the memory cells 130. The second DL contact structures 134 and third DL contact structures 138 may be considered to be so-called “edge of array” DL contact structures. An individual second DL contact structure 134 may be formed to have an upper surface in physical contact with one of the RDM structures 126; and a lower surface on, within, or below one of the DL structures 122. As shown in FIG. 1B, in some embodiments, an individual second DL contact structure 134 is formed to terminate below one of the DL structures 122, such that a lower boundary of the second DL contact structure 134 is positioned below a lower boundary of the DL structure 122 (e.g., within vertical boundaries of one of the second isolation structures 114B). Outer sidewalls of the second DL contact structure 134 may physically contact inner sidewalls of the DL structure 122. In addition, an individual third DL contact structure 138 may be formed to have an upper surface in physical contact with one of the first routing structures 140; and a lower surface on, within, or below one of the RDM structures 126. The second DL contact structures 134 and third DL contact structures 138 may respectively be formed of and include conductive material. In some embodiments, the second DL contact structures 134 and third DL contact structures 138 are individually formed of and include one or more of W, Ru, Mo, and TiN_{y}.

Referring to FIG. 1C, depicted is a simplified, partial plan view of a portion of the memory array structure 100 including the array region 102 and one of the DL exit regions 104. As shown in FIG. 1C, the memory array structure 100 may be configured to have a “socket out-of-array” layout (e.g., arrangement) of DL contact structures, wherein all of the third DL contact structures 138 and all of the second DL contact structures 134 (FIG. 1B) are within horizontal areas of the DL exit regions 104. In such a layout, the third DL contact structures 138 and the second DL contact structures 134 (FIG. 1B) may not vertically overlie and horizontally overlap any inactive WL structures 116D (also referred to herein as “dummy WL structures” 116D). The memory array structure 100 may exhibit a similar “socket out-of-array” layout of WL contact structures, wherein all of the second WL contact structures 136 (FIG. 1B) and all of the first WL contact structures 132 (FIG. 1B) are within horizontal areas of the WL exit regions 106 (FIG. 1B).

Referring again to FIG. 1B, an isolation material 142 may be formed on or over portions of at least the base structure 108, the first dielectric material 120, the DL capping structures 124, the RDM structures 126, the storage node devices 128, the memory cells 130, the first WL contact structures 132, the second WL contact structures 136, the second DL contact structures 134, the third DL contact structures 138, and the first routing structures 140. The isolation material 142 may be formed of and include at least one insulative material. In some embodiments, the isolation material 142 is formed of and includes dielectric oxide material, such as SiOₓ (e.g., SiO₂). The isolation material 142 may be substantially homogeneous, or the isolation material 142 may be heterogeneous. An upper surface of the isolation material 142 may be formed to be substantially planar. In some embodiments, the upper surface of the isolation material 142 is formed to be substantially coplanar with upper surfaces of uppermost ones of the first routing structures 140. In additional embodiments, the upper surface of the isolation material 142 is formed vertically overlie the upper surfaces of the uppermost ones of the first routing structures 140.

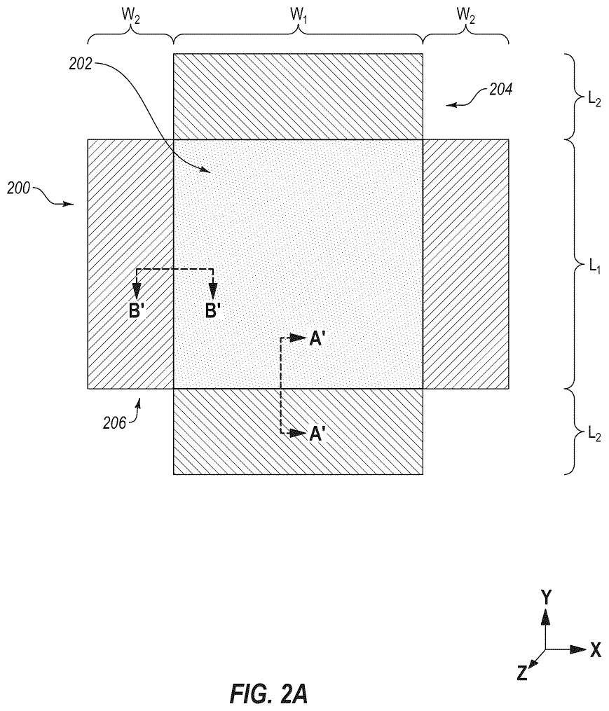

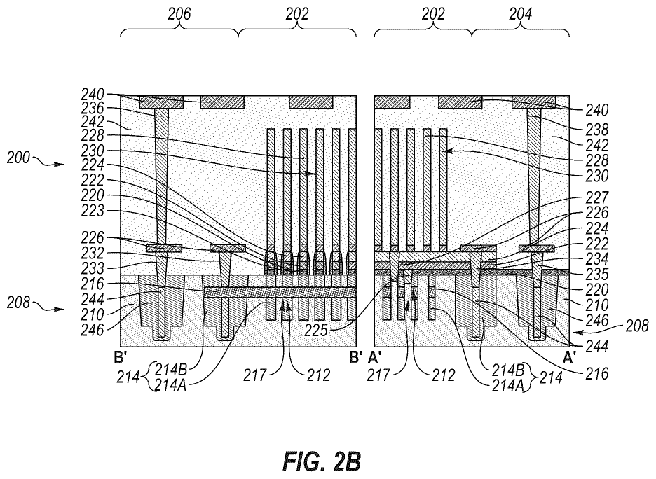

Referring next to FIG. 2A, depicted is a simplified, partial plan view of an additional memory array structure 200 (e.g., a second wafer, a second die) at a processing stage of the method of forming a microelectronic device, in accordance with embodiments of the disclosure. The additional memory array structure 200 is formed separate from the memory array structure 100 (FIGS. 1A-1C) and is configured to be attached (e.g., bonded) to the memory array structure 100 (FIGS. 1A-1C), as described in further detail below. As shown in FIG. 2A, the additional memory array structure 200 may be formed to include an additional array region 202, additional DL exit regions 204 (also referred to as “additional DL contact socket regions”) horizontally neighboring the additional array region 202 in a Y-direction (e.g., a first horizontal direction), and additional WL exit regions 206 (also referred to as “additional WL contact socket regions”) horizontally neighboring the additional array region 202 in an X-direction (e.g., a second horizontal direction) orthogonal to the Y-direction. The additional array region 202, the additional DL exit regions 204, and the additional WL exit regions 206 are each described in further detail below. FIG. 2B is a diagram showing different vertical cross-sectional views of the additional memory array structure 200 shown in FIG. 2A, taken about lines A′-A′ and B′-B′ of FIG. 2A. The vertical cross-section of the additional memory array structure 200 taken about line A′-A′ is a view of a YZ-plane of a portion of the additional memory array structure 200 horizontally overlapping the additional array region 202 and one of the additional DL exit regions 204 of the additional memory array structure 200. The vertical cross-section of the additional memory array structure 200 taken about line B′-B′ is a view of a XZ-plane of an additional portion of the additional memory array structure 200 overlapping the additional array region 202 and one of the additional WL exit regions 206 of the additional memory array structure 200.

Referring collectively to FIGS. 2A and 2B, the additional memory array structure 200 includes features (e.g., regions, sections, structures, circuitry, devices) functionally similar to respective features of the memory array structure 100 previously described with reference to FIGS. 1A-1C. In FIGS. 2A and 2B, and subsequent figures, such features of the additional memory array structure 200 will be understood to be “additional” features, and are referred to with reference numerals similar to those for respective features of the memory array structure 100, but incremented by 100. To avoid repetition, not all features shown in FIGS. 2A and 2B (and subsequent figures) are described in detail herein. Rather, unless described otherwise below, an “additional” feature in one or more of FIGS. 2A and 2B designated by a reference numeral that is a 100 increment of the reference numeral of a feature previously described with reference to one or more of FIGS. 1A-1C will be understood to be substantially similar to and have substantially the same advantages as the previously described feature. As a non-limiting example, in FIG. 2B, additional memory cells 230 may be substantially similar to the memory cells 130 previously described herein with reference to FIG. 1B. As an additional non-limiting example, in FIG. 2B, additional WL structures 216 may be substantially similar to the WL structures 116 previously described herein with reference to FIG. 1B. As a further non-limiting example, in FIG. 2B, additional DL structures 222 may be substantially similar to the DL structures 122 previously described herein with reference to FIG. 1B.

Referring to FIG. 2A, the additional array regions 202 of the memory array structure 100 may respectively have the first width W₁ in the X-direction and the first length L₁ in the Y-direction orthogonal to the X-direction. Furthermore, the additional DL exit regions 204 of the additional memory array structure 200 may respectively have the first width W₁ in the X-direction and the second length L₂ in the Y-direction; and the additional WL exit regions 206 of the additional memory array structure 200 may respectively have the second width W₂ in the X-direction and the first length L₁ in the Y-direction. Accordingly, a horizontal area of an individual additional array region 202 may be substantially the same as a horizontal area of an individual array region 102 (FIG. 1A) of the memory array structure 100 (FIG. 1A); a horizontal area of an individual additional DL exit region 204 may be substantially the same as a horizontal area of an individual DL exit region 104 (FIG. 1A) of the memory array structure 100 (FIG. 1A); and a horizontal area of an individual additional WL exit region 206 may be substantially the same as a horizontal area of an individual WL exit region 106 (FIG. 1A) of the memory array structure 100 (FIG. 1A). However, as described in further detail below, an individual additional array region 202, an individual additional DL exit region 204, and/or an individual additional WL exit region 206 may have a different distribution and/or a different quantity of at least some additional features therein as compared to a distribution and/or a quantity of at least some corresponding features within an individual array region 102 (FIGS. 1A and 1B), an individual DL exit region 104 (FIGS. 1A and 1B), and/or an individual WL exit region 106 (FIGS. 1A and 1B), respectively.

Referring to FIG. 2B, in addition to the features previously described in relation to the memory array structure 100 (FIGS. 1A-1C), the additional memory array structure 200 further includes anchor contact structures 244 (also referred to herein as “A-CON” structures) within horizontal areas of some of the additional isolation structures 214. The anchor contact structures 244 may be formed to vertically extend through the some of the additional isolation structures 214 and into portions of the additional semiconductor material 210 vertically underlying the some of the additional isolation structures 214. An individual anchor contact structure 244 may, for example, vertically extend from below an upper surface of a respective additional isolation structure 214, partially through the additional isolation structure 214, and to a vertical position within the additional semiconductor material 210 vertically underlying a lowermost boundary (e.g., a lowermost surface) of the additional isolation structure 214. The anchor contact structures 244 may vertically extend partially (e.g., less than completely) through portions of the additional semiconductor material 210 vertically underlying the additional isolation structures 214. A lower vertical boundary (e.g., bottom) of an individual anchor contact structure 244 vertically underlies a lower vertical boundary (e.g., bottom) of a respective additional isolation structure 214 that the anchor contact structure 244 horizontally overlaps and vertically extends through. The anchor contact structures 244 may individually be formed of and include conductive material. In some embodiments, the anchor contact structures 244 are individually formed of and include metallic material, such one or more of W, Ru, Mo, and TiN_{y}.

A dielectric liner material 246 may be formed on or over surfaces (e.g., side surfaces, bottom surfaces) of the anchor contact structures 244. In some embodiments, the dielectric liner material 246 substantially continuously extends over and substantially covers portions of side surfaces and bottom surfaces of the anchor contact structures 244. The dielectric liner material 246 may be interposed between the anchor contact structures 244 and the additional semiconductor material 210 of the additional base structure 208. The dielectric liner material 246 may have a thickness within a range of from about two (2) nm to about 10 nm, such as from about 2 nm to about 8 nm, or from about 2 nm to about 5 nm. The dielectric liner material 246 may be formed of and include insulative material. In some embodiments, the dielectric liner material 246 is formed of and includes dielectric oxide material (e.g., SiOₓ, such as SiO₂).

Still referring to FIG. 2B, within the additional WL exit regions 206, the additional memory array structure 200 includes first additional WL contact structures 232, second additional WL contact structures 236, and third additional WL contact structures 233. The first additional WL contact structures 232 and the third additional WL contact structures 233 may be located at substantially the same vertical position (e.g., vertical elevation) as one another, and may be horizontally offset from and electrically isolated from one another. The second additional WL contact structures 236 may be vertically offset from (e.g., vertically overlic) the first additional WL contact structures 232 and the third additional WL contact structures 233, may be horizontally offset from and electrically isolated from the first additional WL contact structures 232, and may be coupled to and horizontally overlap the third additional WL contact structures 233. The first additional WL contact structures 232, the second additional WL contact structures 236, and the third additional WL contact structures 233 may be considered “edge-of-array” additional WL contact structures. The first additional WL contact structures 232, the second additional WL contact structures 236, and the third additional WL contact structures 233 may respectively be formed of and include conductive material. In some embodiments, the first additional WL contact structures 232, the second additional WL contact structures 236, and the third additional WL contact structures 233 are individually formed of and include one or more of W, Ru, Mo, and TiN_{y}.

The first additional WL contact structures 232 may vertically extend between and couple a group of the additional RDM structures 226 and a group of the additional WL structures 216. An individual first additional WL contact structure 232 may be formed to have an upper surface in physical contact with one (1) additional RDM structure 226 of the group of the additional RDM structures 226; and a lower surface on, within, or below one (1) additional WL structure 216 of the group of the additional WL structures 216. The first additional WL contact structures 232 may also be coupled to a group of the anchor contact structures 244 vertically underlying and coupled to the group of the additional WL structures 216.

The third additional WL contact structures 233 may vertically extend between and couple an additional group of the additional RDM structures 226 and an additional group of the anchor contact structures 244. An individual third additional WL contact structure 233 may be formed to have an upper surface in physical contact with one (1) additional RDM structure 226 of the additional group of additional RDM structures 226; and a lower surface on or within one (1) anchor contact structure 244 of the additional group of the anchor contact structures 244. The third additional WL contact structures 233 may physically contact (e.g., land on) the additional group of the anchor contact structures 244. The third additional WL contact structures 233 may be electrically isolated from the additional WL structures 216.

The second additional WL contact structures 236 may vertically extend between and couple the additional group of the additional RDM structures 226 and a group of the first additional routing structures 240 vertically overlying the additional memory cells 230. An individual second additional WL contact structure 236 may be formed to have an upper surface in physical contact with one (1) first additional routing structure 240 of the group of the first additional routing structures 240; and a lower surface on, within, or below one (1) additional RDM structure 226 of the additional group of the additional RDM structures 226. The second additional WL contact structures 236, the additional group of the additional RDM structures 226, the third additional WL contact structures 233, and the additional group of the anchor contact structures 244 may, in combination, form deep WL contact assemblies horizontally offset from the first additional WL contact structures 232 (and the additional WL structures 216) and substantially vertically extending through the additional memory array structure 200.

Still referring to FIG. 2B, within the additional DL exit regions 204, the additional memory array structure 200 includes second additional DL contact structures 234, third additional DL contact structures 238, and fourth additional DL contact structures 235. The second additional DL contact structures 234 and the fourth additional DL contact structures 235 may be located at substantially the same vertical position (e.g., vertical elevation) as one another, and may be horizontally offset from and electrically isolated from one another. The third additional DL contact structures 238 may be vertically offset from (e.g., vertically overlic) the second additional DL contact structures 234 and the fourth additional DL contact structures 235, may be horizontally offset from and electrically isolated from the second additional DL contact structures 234, and may be coupled to and horizontally overlap the fourth additional DL contact structures 235. The second additional DL contact structures 234, the third additional DL contact structures 238, and the fourth additional DL contact structures 235 may be considered “edge-of-array” additional DL contact structures. The second additional DL contact structures 234, the third additional DL contact structures 238, and the fourth additional DL contact structures 235 may respectively be formed of and include conductive material. In some embodiments, the second additional DL contact structures 234, the third additional DL contact structures 238, and the fourth additional DL contact structures 235 are individually formed of and include one or more of W, Ru, Mo, and TiN_{y}.

The second additional DL contact structures 234 may vertically extend between and couple a further group of the additional RDM structures 226 and a group of the additional DL structures 222. An individual second additional DL contact structure 234 may be formed to have an upper surface in physical contact with one (1) additional RDM structure 226 of the further group of the additional RDM structures 226; and a lower surface on, within, or below one (1) additional DL structure 222 of the group of the additional DL structures 222. As shown in FIG. 2B, in some embodiments, an individual second additional DL contact structure 234 is formed to terminate below one of the additional DL structures 222, such that a lower boundary of the second additional DL contact structure 234 is positioned below a lower boundary of the additional DL structure 222 (e.g., within vertical boundaries of one of the second additional isolation structures 214B). The second additional DL contact structures 234 may also be coupled to a further group of the anchor contact structures 244 vertically underlying and coupled to the group of the additional DL structures 222. The second additional DL contact structures 234 may physically contact (e.g., land on) the further group of the anchor contact structures 244.

The fourth additional DL contact structures 235 may vertically extend between and couple an other group of the additional RDM structures 226 and an other group of the anchor contact structures 244. An individual fourth additional DL contact structure 235 may be formed to have an upper surface in physical contact with one (1) additional RDM structure 226 of the other group of additional RDM structures 226; and a lower surface on or within one (1) anchor contact structure 244 of the other group of the anchor contact structures 244. The fourth additional DL contact structures 235 may physically contact (e.g., land on) the other group of the anchor contact structures 244. The fourth additional DL contact structures 235 may be electrically isolated from the additional DL structures 222.

The third additional DL contact structures 238 may vertically extend between and couple the other group of the additional RDM structures 226 and an other group of the first additional routing structures 240 vertically overlying the additional memory cells 230. An individual second additional WL contact structure 236 may be formed to have an upper surface in physical contact with one (1) first additional routing structure 240 of the other group of the first additional routing structures 240; and a lower surface on, within, or below one (1) additional RDM structure 226 of the other group of the additional RDM structures 226. The third additional DL contact structures 238, the other group of the additional RDM structures 226, the fourth additional DL contact structures 235, and the other group of the anchor contact structures 244 may, in combination, form deep DL contact assemblies horizontally offset from the second additional DL contact structures 234 (and the additional DL structures 222) and substantially vertically extending through the additional memory array structure 200.

Similar to the memory array structure 100 (FIGS. 1A-1C), the additional memory array structure 200 may be configured to have a “socket out-of-array” layout (e.g., arrangement) of additional DL contact structures, wherein all of the second additional DL contact structures 234, the third additional DL contact structures 238, and the fourth additional DL contact structures 235 are within horizontal areas of the additional DL exit regions 204. In such a layout, the second additional DL contact structures 234, the third additional DL contact structures 238, and the fourth additional DL contact structures 235 may not vertically overlie and horizontally overlap any additional inactive WL structures (additional dummy WL structures) of the additional memory array structure 200. The additional memory array structure 200 may exhibit a similar “socket out-of-array” layout of additional WL contact structures, wherein all of the first additional WL contact structures 232, second additional WL contact structures 236, and third additional WL contact structures 233 are within horizontal areas of the additional WL exit regions 206.

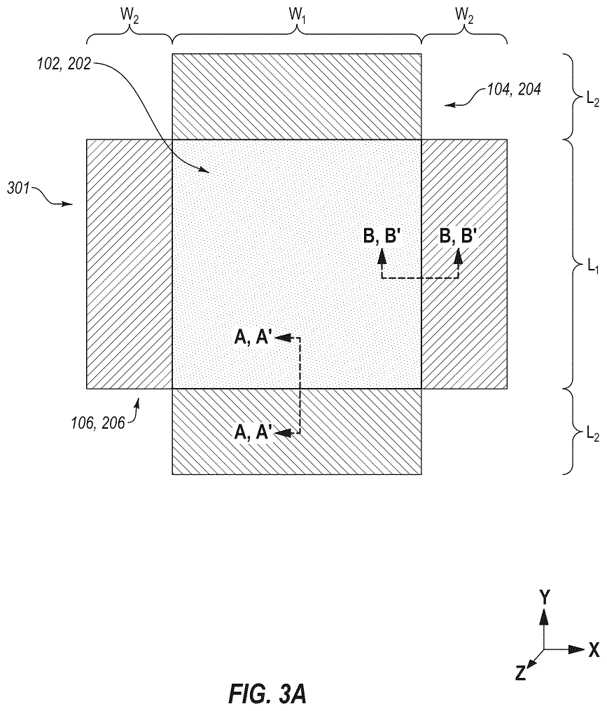

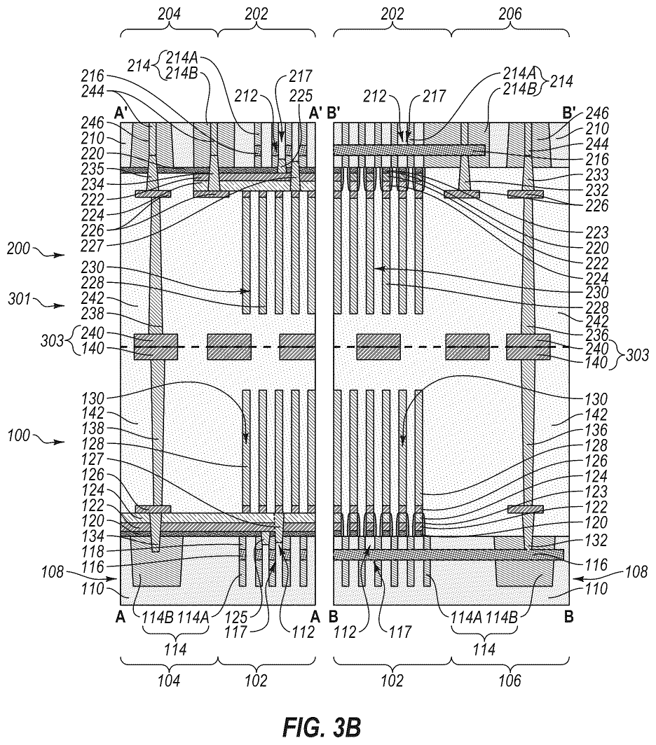

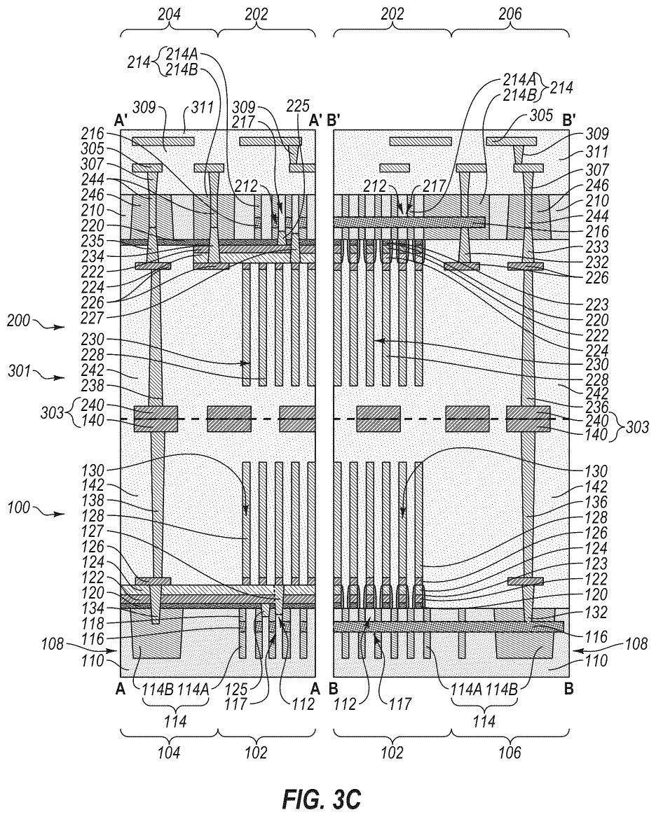

Referring next to FIG. 3A, depicted is a simplified, partial plan view of a first assembly 301 formed from the memory array structure 100 (FIGS. 1A-1C) and the additional memory array structure 200 (FIGS. 2A and 2B) at a processing stage of the method of forming a microelectronic device following the processing stage of FIGS. 1A-IC and the processing stage of FIGS. 2A and 2B. The additional memory array structure 200 may be vertically inverted and attached (e.g., bonded) to the memory array structure 100 to form the first assembly 301. FIG. 3B is a diagram showing different vertical cross-sectional views of the first assembly 301 shown in FIG. 3A at the processing stage of FIG. 3A. As shown collectively in FIGS. 3A and 3B, within the first assembly 301, additional array region 202, the additional DL exit regions 204, and the additional WL exit regions 206 of the additional memory array structure 200 may vertically overlie (e.g., in the Z-direction shown in FIG. 3A) and horizontally overlap (e.g., in the X-direction and the Y-direction shown in FIG. 3A) the array region 102, the DL exit regions 104, and the WL exit regions 106 of the memory array structure 100, respectively. The first assembly 301 may be formed such that the vertical cross-section of the additional memory array structure 200 taken about line A′-A′ of FIG. 2A vertically overlies and horizontally overlaps the vertical cross-section of the memory array structure 100 taken about line A-A of FIG. 1A; and such that the vertical cross-section of the additional memory array structure 200 taken about line B′-B′ of FIG. 2A vertically overlies and horizontally overlaps the vertical cross-section of the memory array structure 100 taken about line B-B of FIG. 1A. The vertical cross-section of the first assembly 301 about the combination of line A-A of the memory array structure 100 and line A′-A′ of the additional memory array structure 200 is a view of a YZ-plane of a portion of the first assembly 301 horizontally overlapping the array region 102 and one of the DL exit regions 104 of the memory array structure 100 as well as the additional array region 202 and one of the additional DL exit regions 204 of the additional memory array structure 200. In addition, the vertical cross-section of the first assembly 301 about the combination of line B-B of the memory array structure 100 and line B′-B′ of the additional memory array structure 200 is a view of an XZ-plane of an additional portion of the first assembly 301 horizontally overlapping the array region 102 and one of the WL exit regions 106 of the memory array structure 100 as well as the additional array region 202 and one of the additional WL exit regions 206 of the additional memory array structure 200.

To form the first assembly 301, the additional isolation material 242 and at least some of the first additional routing structures 240 of the additional memory array structure 200 may be provided in physical contact with the isolation material 142 and at least some of the first routing structures 140 of the memory array structure 100, respectively; and then then the additional isolation material 242, the isolation material 142, the first additional routing structures 240, and the first routing structures 140 may be exposed to annealing conditions to form bonds (e.g., dielectric-to-dielectric bonds, such as oxide-to-oxide bonds) between the additional isolation material 242 and the isolation material 142, and additional bond (e.g., metal-to-metal bonds) between the first additional routing structures 240 and the first routing structures 140. By way of non-limiting example, the additional isolation material 242, the isolation material 142, the first additional routing structures 240, and the first routing structures 140 may be exposed to a temperature greater than or equal to about 400° C. (e.g., within a range of from about 400° C. to about 800° C., greater than about 800° C.) to form bonds between the additional isolation material 242 and the isolation material 142 and bonds between the first additional routing structures 240 and the first routing structures 140. As shown in FIG. 3B, bonding the first additional routing structures 240 to the first routing structures 140 may form bonded routing structures 303. An individual bonded routing structure 303 may include a lower portion including an individual first routing structure 140, and an upper portion integral and continuous within the lower portion and including an individual first additional routing structure 240. While FIG. 3B includes a dashed line representing an initial interface location between the additional memory array structure 200 and the memory array structure 100 before the bonding process, the additional isolation material 242 and the isolation material 142 may be integral and continuous with one another following the bonding process, and the portions (e.g., upper portion formed from a first additional routing structure 240, lower portion formed from a first routing structure 140) of individual bonded routing structures 303 may also be integral and continuous with one another following the bonding process. The additional memory array structure 200 may be attached to the memory array structure 100 without a bond line.

For the formation of the first assembly 301, a front side of the additional memory array structure 200 may be considered a side (e.g., end surface) most proximate to the first additional routing structures 240, and a back side of the memory array structure 100 may be considered an additional side (e.g., additional end surface) most proximate to the additional base structure 208. In addition, a front side of the memory array structure 100 may be considered a side (e.g., end surface) most proximate to the first routing structures 140, and a back side of the memory array structure 100 may be considered an additional side (e.g., additional end surface) most proximate to the base structure 108. Accordingly, in the configuration shown in FIG. 3B, the first assembly 301 may be formed to have a so-called “front-to-front” (F2F) arrangement (also referred to herein as a “face-to-face” arrangement) of the additional memory array structure 200 relative to the memory array structure 100 following the processing stage described with reference to FIGS. 3A and 3B.

As shown in FIG. 3B, following the formation of the first assembly 301, within overlapping horizontal areas of the additional WL exit regions 206 and the WL exit regions 106, the deep WL contact assemblies (including the second additional WL contact structures 236, the additional group of the additional RDM structures 226, the third additional WL contact structures 233, and the additional group of the anchor contact structures 244 thereof) of the additional memory array structure 200 may be coupled (e.g., by way of some of the bonded routing structures 303) to respective combinations of the second WL contact structures 136, the RDM structures 126, and the first WL contact structures 132 of the memory array structure 100 to form conductive paths vertically extending to the WL structures 116. In addition, the group of the anchor contact structures 244 may form additional conductive paths vertically extending to the additional WL structures 216.

As also shown in FIG. 3B, following the formation of the first assembly 301, within overlapping horizontal areas of the additional DL exit regions 204 and the DL exit regions 104, the deep DL contact assemblies (including third additional DL contact structures 238, the other group of the additional RDM structures 226, the fourth additional DL contact structures 235, and the other group of the anchor contact structures 244 thereof) of the additional memory array structure 200 may be coupled (e.g., by way of some other of the bonded routing structures 303) to respective combinations of the third DL contact structures 138, the RDM structures 126, and the second DL contact structures 134 of the memory array structure 100 to form further conductive paths vertically extending to the DL structures 122. In addition, respective combinations of the further group of the additional RDM structures 226 and the second additional DL contact structures 234 may form other conductive paths vertically extending to the additional DL structures 222.

After attaching the additional memory array structure 200 to the memory array structure 100, portions (e.g., upper portions following the vertical inversion of the additional memory array structure 200) of at least the additional semiconductor material 210, the dielectric liner material 246 (if any), and the anchor contact structures 244 may be removed. The material removal process may also remove portions (e.g., upper portions following the vertical inversion of the additional memory array structure 200) of and the additional isolation structures 214. Following the removal process, upper surfaces of remaining portions of the additional semiconductor material 210, the additional isolation structures 214, the anchor contact structures 244, and the dielectric liner material 246 (if any) may be exposed (e.g., uncovered). The exposed upper surfaces of the remaining portions of the additional semiconductor material 210, the additional isolation structures 214, the anchor contact structures 244, and the dielectric liner material 246 (if any) may be substantially coplanar with one another.

The portions of at least the additional semiconductor material 210, the dielectric liner material 246 (if any), and the anchor contact structures 244 may be removed by performing at least one thinning process (e.g., a CMP process; an etching process, such as a conventional dry etching process or a wet etching process) on the portions of the additional semiconductor material 210, the dielectric liner material 246 (if any), and the anchor contact structures 244. The remaining portions of the additional semiconductor material 210, the additional isolation structures 214, the anchor contact structures 244, the dielectric liner material 246 (if any) may be formed to exhibit a desired vertical height (e.g., in the Z-direction) through the material removal process, such as a vertical height less than or equal to about 1500 nm, such as within a range of from about 200 nm to about 1500 nm, from about 200 nm to about 1000 nm, from about 200 nm to about 500 nm, or about 200 nm. In this regard, the anchor contact structures 244 may control stresses during the thinning process (as well as the attachment processes previously described) to facilitate a relatively smaller vertical height of the additional semiconductor material 210 than may otherwise be facilitated through conventional methods.

Referring next to FIG. 3C, illustrated is a diagram showing the different simplified, vertical cross-sectional views previously described with reference to FIG. 3B, at a processing stage of the method of forming the microelectronic device following the processing stage previously described with reference to FIGS. 3A and 3B. First interconnect structures 307 may be formed over and in contact with the anchor contact structures 244, and at least one routing tier (e.g., at least two routing tiers) including second routing structures 305 may be formed over and in contact with the first interconnect structures 307. In addition, second interconnect structures 309 may be formed to couple different second routing structures 305 with one another, as desired.

As shown in FIG. 3C, individual first interconnect structures 307 may be formed to contact (e.g., physically contact, electrically contact) individual anchor contact structures 244. The first interconnect structures 307 may respectively be formed to at least partially horizontally overlap one of the anchor contact structures 244. In some embodiments, a horizonal center of an individual first interconnect structure 307 is substantially aligned with a horizonal center of one of the anchor contact structures 244 vertically thereunder and partially exposed thereby. A horizontal area of a lower surface of an individual first interconnect structure 307 may be less than, substantially equal to, or greater than a horizontal area of an upper surface of an individual anchor contact structure 244 vertically underlying and horizontally overlapping the first interconnect structure 307. The first interconnect structures 307 may respectively be formed of and include conductive material. In some embodiments, the first interconnect structures 307 are individually formed of and include one or more of W, Cu, Al, Ru, Mo, and TiN_{y}.

The second routing structures 305 may be formed to vertically overlie the first interconnect structures 307. As shown in FIG. 3C, some of the second routing structures 305 may be coupled to the first interconnect structures 307 (and, hence, the anchor contact structures 244). If multiple tiers of the second routing structures 305 are formed, at least some of the second routing structures 305 of one of the tiers may be coupled to at least some of the second routing structures 305 of another one of the tiers by way of the second interconnect structures 309. The second routing structures 305 and the second interconnect structures 309 may respectively be formed of and include conductive material. In some embodiments, the second routing structures 305 and the second interconnect structures 309 are individually formed of and include one or more of W, Cu, Al, Ru, Mo, and TiN_{y}.

Still referring to FIG. 3C, a first insulative material 311 may be formed on or over portions of at least the additional semiconductor material 210, the dielectric liner material 246 (if any), the anchor contact structures 244, the first interconnect structures 307, the second routing structures 305, and the second interconnect structures 309. In some embodiments, the first insulative material 311 is formed of and includes a dielectric oxide material, such as SiOₓ (e.g., SiO₂). The first insulative material 311 may be substantially homogeneous, or the first insulative material 311 may be heterogeneous. In some embodiments, an upper surface of the first insulative material 311 is formed to vertically overlie upper surfaces of uppermost ones of the second routing structures 305. In additional embodiments, an upper surface of the first insulative material 311 is formed to be substantially coplanar with upper surfaces of uppermost ones of the second routing structures 305.

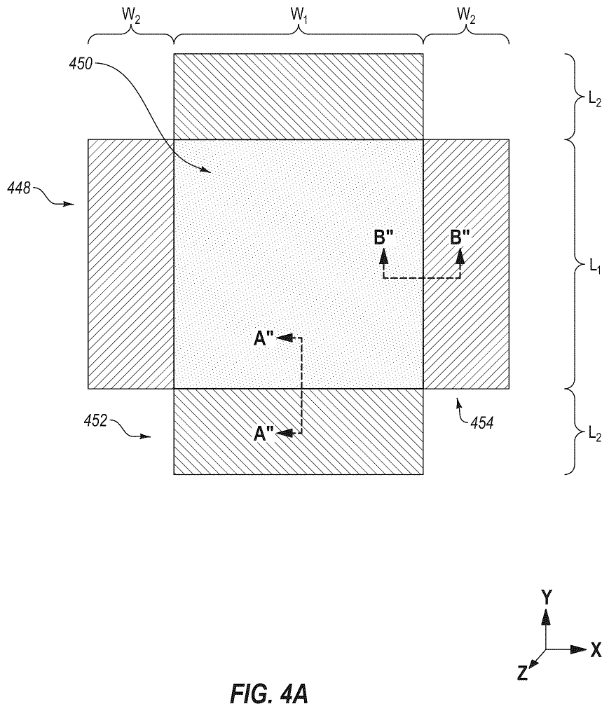

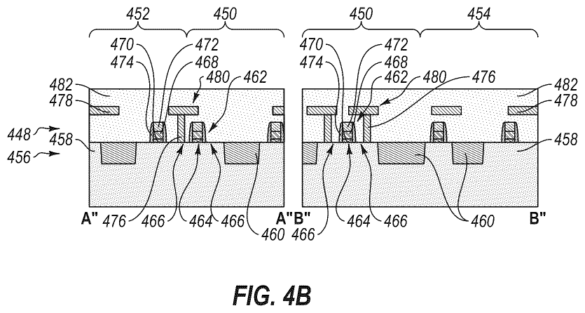

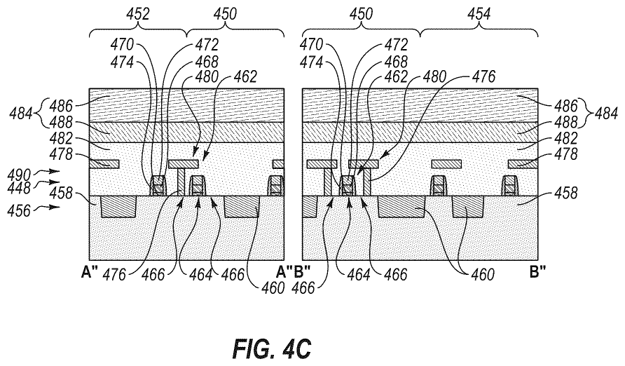

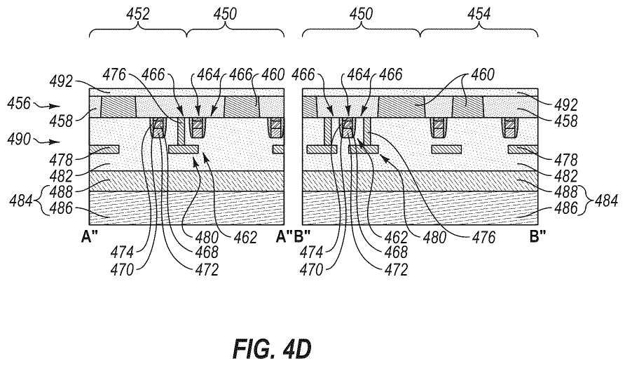

Referring next to FIG. 4A, illustrated is a simplified, partial plan view of a control circuitry structure 448 (e.g., a third wafer, a third die) at a processing stage of the method of forming a microelectronic device, in accordance with embodiments of the disclosure. The control circuitry structure 448 is formed separate from each of the memory array structure 100 (FIGS. 1A-1C) and the additional memory array structure 200 (FIGS. 2A and 2B), and is configured to be attached (e.g., bonded) to the first assembly 301 (FIG. 3C), as described in further detail below. As shown in FIG. 4A, the control circuitry structure 448 may be formed to include a control circuitry region 450, first peripheral regions 452 horizontally neighboring the control circuitry region 450 in a Y-direction (e.g., a first horizontal direction), and second peripheral regions 454 horizontally neighboring the control circuitry region 450 in an X-direction (e.g., a second horizontal direction) orthogonal to the Y-direction. The control circuitry region 450, the first peripheral regions 452, and the second peripheral regions 454 are each described in further detail below. FIG. 4B is a diagram showing different vertical cross-sectional views of the control circuitry structure 448 shown in FIG. 4A, taken about lines A″-A″ and B″-B″ of FIG. 4A. The vertical cross-section of the control circuitry structure 448 taken about line A″-A″ is a view of a YZ-plane of a portion of the control circuitry structure 448 horizontally overlapping the control circuitry region 450 and one of the first peripheral regions 452 of the control circuitry structure 448. The vertical cross-section of the control circuitry structure 448 taken about line B″-B″ is a view of an XZ-plane of an additional portion of the control circuitry structure 448 overlapping the control circuitry region 450 and one of the second peripheral regions 454 of the control circuitry structure 448.

Referring to FIG. 4A, the control circuitry region 450 of the control circuitry structure 448 includes control logic circuitry of the control circuitry structure 448 within a horizontal area thereof. The control logic circuitry of the control circuitry region 450 of the control circuitry structure 448 may be configured to be operatively associated with circuitry (e.g., memory cells, additional memory cells) of the memory array structure 100 (FIG. 3C) and the additional memory array structure 200 (FIG. 3C) of the first assembly 301 (FIG. 3C), as described in further detail below. In some embodiments, the control circuitry region 450 is configured to at least partially (e.g., substantially) horizontally overlap a respective array region 102 (FIG. 3C) of the memory array structure 100 (FIG. 3C) as well as a respective additional memory array region 202 (FIG. 3C) of the additional memory array structure 200 (FIG. 3C) following subsequent attachment of the control circuitry structure 448 to the first assembly 301 (FIG. 3C), as also described in further detail below. For clarity and case of understanding of the drawings and related description, FIG. 4A depicts the control circuitry structure 448 as including one (1) control circuitry region 450, but the control circuitry structure 448 may be formed to include multiple (e.g., more than one (1)) control circuitry regions 450 horizontally offset (e.g., in one or more of the X-direction and the Y-direction) from one another. For example, the control circuitry structure 448 may include greater than or equal to four (4) control circuitry regions 450, greater than or equal to eight (8) control circuitry regions 450, greater than or equal to sixteen (16) control circuitry regions 450, greater than or equal to thirty-two (32) control circuitry regions 450, greater than or equal to sixty-four (64) control circuitry regions 450, greater than or equal to one hundred twenty-eight (128) control circuitry regions 450, greater than or equal to two hundred fifty-six (256) control circuitry regions 450, greater than or equal to five hundred twelve (512) control circuitry regions 450, or greater than or equal to one thousand twenty-four (1024) control circuitry regions 450. In some embodiments, a quantity of the control circuitry regions 450 of the control circuitry structure 448 substantially equals a quantity of the array regions 102 (FIG. 3C) of the memory array structure 100 (FIG. 3C), and also substantially equals a quantity of the additional array regions 202 (FIG. 3C) of the additional memory array structure 200 (FIG. 3C).

The first peripheral regions 452 of the control circuitry structure 448 respectively include additional circuitry (e.g., peripheral circuitry) of the control circuitry structure 448 within a horizontal area thereof. In some embodiments, the first peripheral regions 452 are configured to at least partially (e.g., substantially) horizontally overlap respective DL exit regions 104 (FIG. 3C) of the memory array structure 100 (FIG. 3C) and respective additional DL exit regions 204 (FIG. 3C) of the additional memory array structure 200 (FIG. 3C) following subsequent attachment of the control circuitry structure 448 to the first assembly 301 (FIG. 3C), as described in further detail below. In some embodiments, a quantity of the first peripheral regions 452 of the control circuitry structure 448 substantially equals a quantity of the DL exit regions 104 (FIG. 3C) of the memory array structure 100 (FIG. 3C), and also substantially equals a quantity of the additional DL exit regions 204 (FIG. 3C) of the additional memory array structure 200 (FIG. 3C). As shown in FIG. 4A, the first peripheral regions 452 may respectively horizontally extend in the X-direction. An individual control circuitry region 450 of the control circuitry structure 448 may be horizontally interposed between horizontally neighboring first peripheral regions 452 of the control circuitry structure 448 in the Y-direction.

The second peripheral regions 454 of the control circuitry structure 448 respectively include further circuitry (e.g., further peripheral circuitry) of the control circuitry structure 448 within a horizontal area thereof. In some embodiments, the second peripheral regions 454 are configured to at least partially (e.g., substantially) horizontally overlap respective WL exit regions 106 (FIG. 3C) of the memory array structure 100 (FIG. 3C) and respective additional WL exit regions 206 (FIG. 3C) of the additional memory array structure 200 (FIG. 3C) following subsequent attachment of the control circuitry structure 448 to the first assembly 301 (FIG. 3C), as described in further detail below. In some embodiments, a quantity of the second peripheral regions 454 of the control circuitry structure 448 substantially equals a quantity of the WL exit regions 106 (FIG. 3C) of the memory array structure 100 (FIG. 3C), and also substantially equals a quantity of the additional WL exit regions 206 (FIG. 3C) of the additional memory array structure 200 (FIG. 3C). As shown in FIG. 4A, the second peripheral regions 454 may respectively horizontally extend in the Y-direction. An individual control circuitry region 450 of the control circuitry structure 448 may be horizontally interposed between horizontally neighboring second peripheral regions 454 of the control circuitry structure 448 in the X-direction.

Still referring to FIG. 4A, the control circuitry region 450 of the control circuitry structure 448 may respectively have the first width W₁ in the X-direction and the first length L₁ in the Y-direction orthogonal to the X-direction. Furthermore, the first peripheral regions 452 of the control circuitry structure 448 may respectively have the first width W₁ in the X-direction and the second length L₂ in the Y-direction; and the second peripheral regions 454 of the control circuitry structure 448 may respectively have the second width W₂ in the X-direction and the first length L₁ in the Y-direction. Accordingly, a horizontal area of an individual control circuitry region 450 may be substantially the same as a horizontal area of an individual array region 102 (FIG. 1A) of the memory array structure 100 (FIG. 1A), and may be substantially the same as a horizontal area of an individual additional array region 202 (FIG. 2A) of the additional memory array structure 200 (FIG. 2A); a horizontal area of an individual first peripheral region 452 may be substantially the same as a horizontal area of an individual DL exit region 104 (FIG. 1A) of the memory array structure 100 (FIG. 1A), and may be substantially the same as a horizontal area of an individual additional DL exit region 204 (FIG. 2A) of the additional memory array structure 200 (FIG. 2A); and a horizontal area of an individual second peripheral region 454 may be substantially the same as a horizontal area of an individual WL exit region 106 (FIG. 1A) of the memory array structure 100 (FIG. 1A), and may be substantially the same as a horizontal area of an individual additional WL exit region 206 (FIG. 2A) of the additional memory array structure 200 (FIG. 2A).

Referring next to FIG. 4B, the control circuitry structure 448 may be formed to include a further base structure 456 including further semiconductor material 458 and further isolation structures 460 (e.g., additional STI structures) vertically extending into the further semiconductor material 458.

The further base structure 456 comprises a base material or construction upon which additional features (e.g., materials, structures, devices) of the control circuitry structure 448 are formed. The further base structure 456 may comprise a semiconductor structure (e.g., a semiconductor wafer), or a base semiconductor material on a supporting structure. For example, the further base structure 456 may comprise a conventional silicon substrate (e.g., a conventional silicon wafer), or another bulk substrate comprising a semiconductor material. In some embodiments, the further base structure 456 comprises a silicon wafer. The further base structure 456 may include one or more layers, structures, and/or regions formed therein and/or thereon.

The further isolation structures 460 may comprise trenches (e.g., openings, vias, apertures) within the further semiconductor material 458 of the further base structure 456 filled with insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the further isolation structures 460 are respectively formed of and include SiOₓ (e.g., SiO₂).

The further isolation structures 460 may, for example, be employed as STI structures within the further base structure 456. The further isolation structures 460 may be formed to vertically extend partially (e.g., less than completely) through the further base structure 456. In some embodiments, a vertical depth (e.g., vertical height) of the further isolation structures 460 is within a range of from about 200 nanometers (nm) to about 2000 nm. Each of the further isolation structures 460 may be formed to exhibit substantially the same dimensions and shape as each other of the further isolation structures 460, or at least one of the further isolation structures 460 may be formed to exhibit one or more of different dimensions and a different shape than at least one other of the further isolation structures 460. As a non-limiting example, each of the further isolation structures 460 may be formed to exhibit substantially the same vertical dimension(s) and substantially the same vertical cross-sectional shape(s) as each other of the further isolation structures 460; or at least one of the further isolation structures 460 may be formed to exhibit one or more of different vertical dimension(s) and different vertical cross-sectional shape(s) than at least one other of the further isolation structures 460. In some embodiments, the further isolation structures 460 are all formed to vertically extend to and terminate at substantially the same depth within the further semiconductor material 458 of the further base structure 456. In additional embodiments, at least one of the further isolation structures 460 is formed to vertically extend to and terminate at a relatively deeper depth within the further semiconductor material 458 of the further base structure 456 than at least one other of the further isolation structures 460. As another non-limiting example, each of the further isolation structures 460 may be formed to exhibit substantially the same horizontal dimension(s) and substantially the same horizontal cross-sectional shape(s) as each other of the further isolation structures 460; or at least one of the further isolation structures 460 may be formed to exhibit one or more of different horizontal dimension(s) (e.g., relatively larger horizontal dimension(s), relatively smaller horizontal dimension(s)) and different horizontal cross-sectional shape(s) than at least one other of the further isolation structures 460. In some embodiments, at least one of the further isolation structures 460 is formed to have one or more different horizontal dimensions (e.g., in the X-direction and/or in the Y-direction) than at least one other of the further isolation structures 460.

Still referring to FIG. 4B, the control circuitry structure 448 may further include transistors 462. The transistors 462 may individually include conductively doped regions 466 (e.g., source/drain regions), a channel region 464, a gate structure 468 (e.g., a gate electrode), and a gate dielectric material 470. For an individual transistor 462, the conductively doped regions 466 thereof may be formed within the further semiconductor material 458 of the further base structure 456; the channel region 464 thereof may be formed within the further semiconductor material 458 of the further base structure 456 and may be horizontally interposed between the conductively doped regions 466 thereof; the gate structure 468 thereof may vertically overlie and horizontally overlap the channel region 464 thereof; and the gate dielectric material 470 (e.g., dielectric oxide material) may be vertically interposed (e.g., in the Z-direction (FIG. 4A)) between the gate structure 468 and the channel region 464.

For an individual transistor 462, the conductively doped regions 466 thereof may comprise further semiconductor material 458 of the further base structure 456 doped with one or more desired conductivity-enhancing dopants. In some embodiments, the conductively doped regions 466 of the transistor 462 comprise the further semiconductor material 458 doped with at least one N-type dopant (e.g., one or more of phosphorus, arsenic, antimony, and bismuth). In some of such embodiments, the channel region 464 of the transistor 462 comprises the further semiconductor material 458 doped with at least one P-type dopant (e.g., one or more of boron, aluminum, and gallium). In some other of such embodiments, the channel region 464 of the transistor 462 comprises substantially undoped further semiconductor material 458. In additional embodiments, for an individual transistor 462, the conductively doped regions 466 thereof comprise the further semiconductor material 458 doped with at least one P-type dopant (e.g., one or more of boron, aluminum, and gallium). In some of such additional embodiments, the channel region 464 of the transistor 462 comprises the further semiconductor material 458 doped with at least one N-type dopant (e.g., one or more of phosphorus, arsenic, antimony, and bismuth). In some other of such additional embodiments, the channel region 464 of the transistor 462 comprises substantially undoped further semiconductor material 458.

The gate structures 468 (e.g., gate electrodes, gates) may individually horizontally extend between and be employed by multiple transistors 462. The gate structures 468 may be formed of and include conductive material. The gate structures 468 may individually be substantially homogeneous, or the gate structures 468 may individually be heterogeneous. In some embodiments, the gate structures 468 are each substantially homogeneous. In additional embodiments, the gate structures 468 are each heterogeneous. Individual gate structures 468 may, for example, be formed of and include a stack of at least two different conductive materials.

Still referring to FIG. 4B, the control circuitry structure 448 may further include a dielectric capping structures 472 upper surfaces of the gate structures 468, and dielectric spacer structures 474 on side surfaces of the gate structures 468, the gate dielectric material 470, and the dielectric capping structures 472. In addition, the control circuitry structure 448 further includes first contact structures 476 vertically overlying and in contact (e.g., physical contact, electrical contact) with the conductively doped regions 466 of the transistors 462. In some embodiments, the first contact structures 476 vertically overlie, horizontally overlap, and physically contact the conductively doped regions 466 of the transistors 462. The first contact structures 476 may individually be formed of and include conductive material. In some embodiments, the first contact structures 476 are individually formed of and include one or more of W, Ru, Mo, and TiN_{y}.

The control circuitry structure 448 further includes third routing structures 478 vertically overlying the transistors 462. As shown in FIG. 4B, some of the third routing structures 478 may be coupled to the first contact structures 476 (and, hence, the transistors 462). The third routing structures 478 may respectively be formed of and include conductive material. In some embodiments, the third routing structures 478 are individually formed of and include one or more of W, Ru, Mo, and TiN_{y}.

With continued collective reference to FIG. 4B, the transistors 462, the first contact structures 476, and at least some of the third routing structures 478 may form control logic circuitry of various control logic devices 480 configured to control various operations of various features (e.g., the memory cells 130 (FIG. 3C), the additional memory cells 230 (FIG. 3C)) of a microelectronic device (e.g., a memory device, such as a DRAM device) to be formed through the methods of disclosure. In some embodiments, the control logic devices 480 comprise complementary metal-oxide-semiconductor (CMOS) circuitry. As a non-limiting example, the control logic devices 480 may include one or more (e.g., each) of charge pumps (e.g., Vccp charge pumps, VNEGWI, charge pumps, DVC2 charge pumps), delay-locked loop (DLL) circuitry (e.g., ring oscillators), Vad regulators, drivers (e.g., main WL drivers, sub WL drivers (SWD)), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry. Different regions (e.g., the control circuitry region 450, the first peripheral regions 452, the second peripheral regions 454) of the control circuitry structure 448 may have different control logic devices 480 formed within horizontal areas thereof.

A second insulative material 482 may be formed on or over portions of at least the further base structure 456, the transistors 462, the first contact structures 476, the third routing structures 478, and the control logic devices 480. In some embodiments, the second insulative material 482 is formed of and includes a dielectric oxide material, such as SiOₓ (e.g., SiO₂). The second insulative material 482 may be substantially homogeneous, or the second insulative material 482 may be heterogeneous. An upper surface of the second insulative material 482 may be formed to be substantially planar. In some embodiments, the upper surface of the second insulative material 482 is formed vertically overlie the upper surfaces of the uppermost ones of the third routing structures 478. In additional embodiments, the upper surface of the second insulative material 482 is formed to be substantially coplanar with upper surfaces of uppermost ones of the third routing structures 478.

Referring next to FIG. 4C, illustrated is a diagram showing the different simplified, vertical cross-sectional views previously described with reference to FIG. 4B, at a processing stage of the method of forming the microelectronic device following the processing stage previously described with reference to FIGS. 4A and 4B. As shown in FIG. 4C, a carrier structure 484 may be attached to the control circuitry structure 448 to form a second assembly 490. The carrier structure 484 may include an other base structure 486 and a third insulative material 488 on the other base structure 486.

The other base structure 486 comprises a base material or construction upon which additional features (e.g., materials, structures, devices) of the formed. In some embodiments, the other base structure 486 comprises a wafer. The other base structure 486 may be formed of and include one or more of semiconductor material (e.g., one or more of a silicon material, such monocrystalline silicon or polycrystalline silicon (also referred to herein as “polysilicon”); silicon-germanium; germanium; gallium arsenide; a gallium nitride; gallium phosphide; indium phosphide; indium gallium nitride; and aluminum gallium nitride), a base semiconductor material on a supporting structure, glass material (e.g., one or more of BSP, PSG, FSG, BPSG, aluminosilicate glass, an alkaline earth boro-aluminosilicate glass, quartz, titania silicate glass, and soda-lime glass), and ceramic material (e.g., one or more of p-AlN, SOPAN, AlN, aluminum oxide (e.g., sapphire; α-Al₂O₃), and silicon carbide). By way of non-limiting example, the other base structure 486 may comprise a semiconductor wafer (e.g., a silicon wafer), a glass wafer, or a ceramic wafer. The other base structure 486 may include one or more layers, structures, and/or regions formed therein and/or thereon.

The third insulative material 488 may cover one or more surfaces of the other base structure 486. In some embodiments, the third insulative material 488 is formed of and includes a dielectric oxide material, such as SiOₓ (e.g., SiO₂). The third insulative material 488 may be substantially homogeneous, or the third insulative material 488 may be heterogeneous.

To attach the carrier structure 484 to the control circuitry structure 448 to form the second assembly 490, the third insulative material 488 of the carrier structure 484 may be provided in physical contact with at least the second insulative material 482 of the control circuitry structure 448, and the third insulative material 488 and the second insulative material 482 may be exposed to annealing conditions to form bonds (e.g., oxide-to-oxide bonds) between the third insulative material 488 and the second insulative material 482. By way of non-limiting example, the third insulative material 488 and the second insulative material 482 may be exposed to a temperature greater than or equal to about 400° C. (e.g., within a range of from about 400° C. to about 800° C., greater than about 800° C.) to form oxide-to-oxide bonds between the third insulative material 488 and the second insulative material 482. In some embodiments, the third insulative material 488 and the second insulative material 482 are exposed to at least one temperature greater than about 800° C. to form oxide-to-oxide bonds between the third insulative material 488 and the second insulative material 482.

Referring next to FIG. 4D, illustrated is a diagram showing the different simplified, vertical cross-sectional views previously described with reference to FIG. 4B, at a processing stage of the method of forming the microelectronic device following the processing stage previously described with reference to FIG. 4C. As shown in FIG. 4D, the second assembly 490 may be vertically inverted, and then at least one thinning process (e.g., a CMP process; an etching process, such as a conventional dry etching process or a wet etching process) may be performed on the further base structure 456 to remove upper portions (following vertical inversion) of at least the further semiconductor material 458 (and, optionally, the further isolation structures 460) to expose the further isolation structures 460. The remaining portions of the further semiconductor material 458 and the further isolation structures 460 may be formed to exhibit a desired vertical height (e.g., in the Z-direction) through the material removal process, such as a vertical height less than or equal to about 1500 nm, such as within a range of from about 200 nm to about 1500 nm, from about 200 nm to about 1000 nm, from about 200 nm to about 500 nm, or about 200 nm.

Still referring to FIG. 4D, after the thinning process, a fourth insulative material 492 may be formed one or over upper surfaces of the remaining portions of the further semiconductor material 458 and the further isolation structures 460. In some embodiments, the fourth insulative material 492 is formed of and includes a dielectric oxide material, such as SiOₓ (e.g., SiO₂). The fourth insulative material 492 may be substantially homogeneous, or the fourth insulative material 492 may be heterogeneous. An upper surface of the fourth insulative material 492 may be formed to be substantially planar.

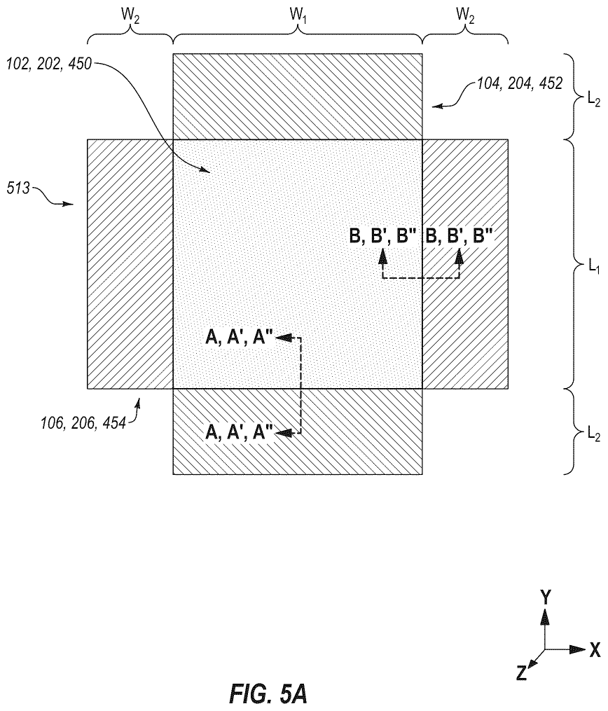

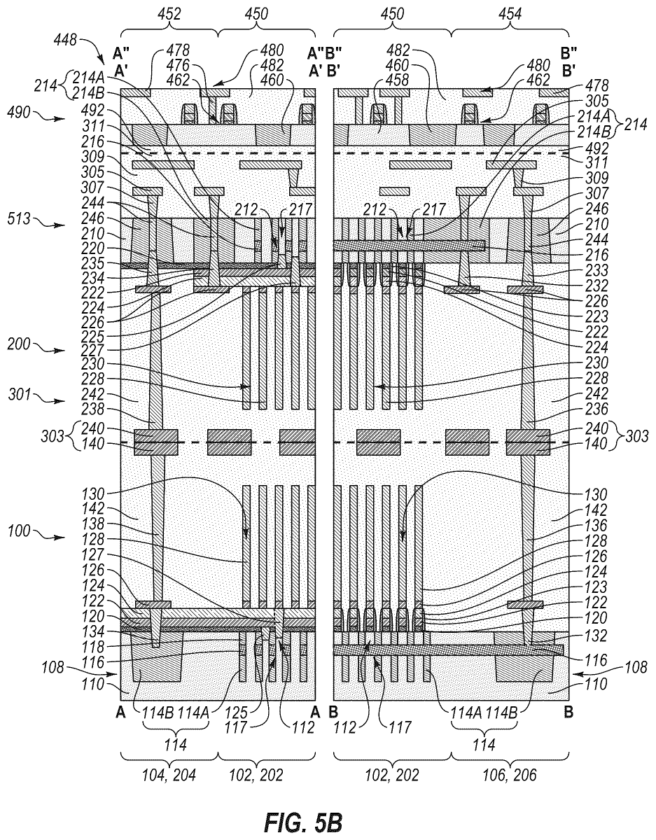

Referring next to FIG. 5A, depicted is a simplified, partial plan view of a third assembly 513 formed from the first assembly 301 (FIG. 3C) and the second assembly 490 (FIG. 4D) at a processing stage of the method of forming a microelectronic device following the processing stage of FIG. 3C and the processing stage of FIG. 4D. The second assembly 490 (FIG. 4D) may be vertically inverted again and attached (e.g., bonded) to the first assembly 301 (FIG. 3C) to form the third assembly 513. FIG. 5B is a diagram showing different vertical cross-sectional views of the third assembly 513 shown in FIG. 5A at the processing stage of FIG. 5A. As shown collectively in FIGS. 5A and 5B, within the third assembly 513, the control circuitry region 450 of the control circuitry structure 448 may vertically overlie (e.g., in the Z-direction shown in FIG. 5A) and horizontally overlap (e.g., in the X-direction and the Y-direction shown in FIG. 5A) each of the array region 102 and the additional array region 202. In addition, within the third assembly 513, the first peripheral region 452 of the control circuitry structure 448 may vertically overlie (e.g., in the Z-direction shown in FIG. 5A) and horizontally overlap (e.g., in the X-direction and the Y-direction shown in FIG. 5A) each of the DL exit region 104 and the additional DL exit region 204. Furthermore, within the third assembly 513, the second peripheral region 454 of the control circuitry structure 448 may vertically overlie (e.g., in the Z-direction shown in FIG. 5A) and horizontally overlap (e.g., in the X-direction and the Y-direction shown in FIG. 5A) each of the WL exit region 106 and the additional WL exit region 206. The third assembly 513 may be formed such that the vertical cross-section of the second assembly 490 taken about line A″-A″ vertically overlies and horizontally overlaps the vertical cross-section of the first assembly 301 taken about lines A-A and A′-A′; and such that the vertical cross-section of the third assembly 513 taken about line B″-B″ vertically overlies and horizontally overlaps the vertical cross-section of the first assembly 301 taken about lines B-B and B′-B′. The vertical cross-section of the third assembly 513 about the combination of previously described lines A-A, A′-A′, and A″-A″ is a view of a YZ-plane of a portion of the third assembly 513 horizontally overlapping the array region 102 and one of the DL exit regions 104 of the memory array structure 100; the additional array region 202 and one of the additional DL exit regions 204 of the additional memory array structure 200; and the control circuitry region 450 and one of the first peripheral regions 452 of the control circuitry structure 448. In addition, the vertical cross-section of the third assembly 513 about the combination of previously described lines B-B, B′-B′, and B″-B″ is a view of an XZ-plane of a portion of the third assembly 513 horizontally overlapping the array region 102 and one of the WL exit regions 106 of the memory array structure 100; the additional array region 202 and one of the additional WL exit regions 206 of the additional memory array structure 200; and the control circuitry region 450 and one of the second peripheral regions 454 of the control circuitry structure 448.

Referring to FIG. 5B, to form the third assembly 513, the fourth insulative material 492 of the second assembly 490 may be provided in physical contact with the first insulative material 311 of the first assembly 301; and then then the fourth insulative material 492 and the first insulative material 311 may be exposed to annealing conditions to form bonds (e.g., dielectric-to-dielectric bonds, such as oxide-to-oxide bonds) between the fourth insulative material 492 and the first insulative material 311. By way of non-limiting example, the fourth insulative material 492 and the first insulative material 311 may be exposed to a temperature greater than or equal to about 400° C. (e.g., within a range of from about 400° C. to about 800° C., greater than about 800° C.) to form bonds between the fourth insulative material 492 and the first insulative material 311. While FIG. 5B includes a dashed line representing an initial interface location between the second assembly 490 and the first assembly 301 before the bonding process, the fourth insulative material 492 and the first insulative material 311 may be integral and continuous with one another following the bonding process. The second assembly 490 may be attached to the first assembly 301 without a bond line. Following the attachment of the second assembly 490 to the first assembly 301, the carrier structure 484 (FIG. 4D) may be removed.

For the formation of the third assembly 513, a front side of the control circuitry structure 448 of the second assembly 490 may be considered to be a side (e.g., end surface) most proximate to the control logic devices 480 (e.g., most proximate to the third routing structures 478), and a back side of the control circuitry structure 448 of the second assembly 490 may be considered to be an additional side (e.g., additional end surface) relatively more distal from the control logic devices 480 (e.g., most proximate to the fourth insulative material 492) than the front side. In addition, as previously described herein front side of the additional memory array structure 200 of the first assembly 301 may be considered to be a side (e.g., end surface) most proximate to the first additional routing structures 240, and a back side of the additional memory array structure 200 of the first assembly 301 may be considered to be an additional side (e.g., additional end surface) most proximate to the additional base structure 208. Accordingly, in the configuration shown in FIG. 5B, the third assembly 513 may be formed to have a so-called “back-to-back” (B2B) arrangement of the control circuitry structure 448 relative to the additional memory array structure 200. In addition, the third assembly 513 may have a F2F arrangement of the additional memory array structure 200 relative to the memory array structure 100.

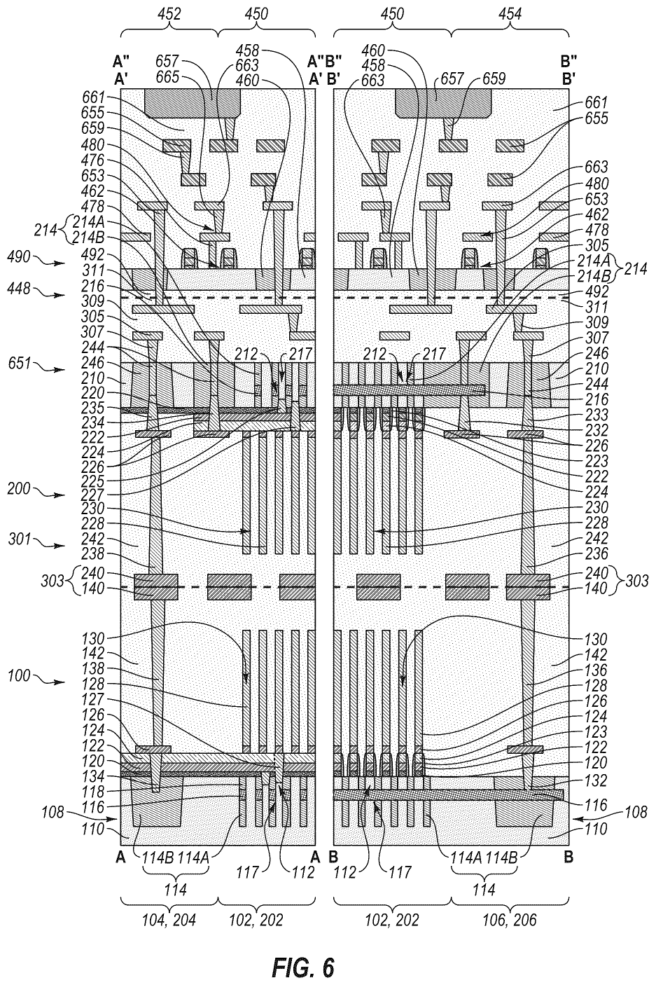

Still referring to FIG. 5B, following the formation of the third assembly 513, at least some of the further isolation structures 460 of the second assembly 490 vertically overlie and horizontally overlap (e.g., in the X-direction and the Y-direction shown in FIG. 5A) at least some of the second routing structures 305 of the first assembly 301. The horizontal positions of the further isolation structures 460 may facilitate the formation of additional conductive contact structures vertically extending through the at least some of the further isolation structures 460 and to the at least some of the second routing structures 305, as described in further detail below with reference to FIG. 6.

Referring next to FIG. 6, illustrated is a diagram showing the different vertical cross-sectional views previously described with reference to FIG. 5B, at a processing stage of the method of forming the microelectronic device following the processing stage previously described with reference to FIG. 5B. As shown in FIG. 6, fourth routing structures 663 may be formed vertically over the control logic devices 480. In addition, second contact structures 665 may be formed to couple at least some of the fourth routing structures 663 to at least some of the control logic devices 480, and third contact structures 653 may be formed to couple at least some of the fourth routing structures 663 to at least some of the second routing structures 305. Furthermore, as described in further detail below, back-end-of-line (BEOL) structures may be formed vertically over the fourth routing structures 663.

The fourth routing structures 663 may be formed to horizontally extend in desirable paths over the control logic devices 480. As shown in FIG. 6, some of the fourth routing structures 663 may be coupled to some of the third routing structures 478 (and, hence, at least some of the control logic devices 480) by way of the second contact structures 665. The second contact structures 665 may vertically extend from the some of the fourth routing structures 663 to the some of the third routing structures 478. The fourth routing structures 663 and the second contact structures 665 may respectively be formed of and include conductive material. In some embodiments, the fourth routing structures 663 and the second contact structures 665 are individually formed of and include one or more of W, Ru, Mo, and TiN_{y}.

With continued reference to FIG. 6, the third contact structures 653 may be formed to vertically extend from some of the fourth routing structures 663 vertically overlying the control logic devices 480 to some of the second routing structures 305 vertically underlying the control logic devices 480. One or more (e.g., each) of the third contact structures 653 may be formed to horizontally overlap and vertically extend through one or more of the further isolation structures 460 (e.g., STI structures) of the control circuitry structure 448. Optionally, one or more other of the third contact structures 653 may be formed to horizontally overlap and vertically extend through the further semiconductor material 458 of the control circuitry structure 448. The third contact structures 653 may facilitate (in combination with at least the second contact structures 665, the fourth routing structures 663, the second routing structures 305, the first interconnect structures 307, the second interconnect structures 309, the anchor contact structures 244, the additional RDM structures 226, the first additional WL contact structures 232, the additional WL structures 216, the third additional WL contact structures 233, the second additional WL contact structures 236, the additional DL contact structures 234, the additional DL structures 222, the fourth additional DL contact structures 235, the third additional DL contact structures 238, the bonded routing structures 303, the RDM structures 126, the second WL contact structures 136, the first WL contact structures 132, the WL structures 116, the third DL contact structures 138, the second DL contact structures 134, and the DL structures 122) operable communication between the control logic devices 480 and each of the additional memory cells 230 and the memory cells 130 vertically thereunder. The third contact structures 653 may respectively be formed of and include conductive material. In some embodiments, the third contact structures 653 are individually formed of and include one or more of W, Ru, Mo, and TiN_{y}.

As previously mentioned, BEOL structures may be formed vertically over the fourth routing structures 663. For example, at least one additional routing tier (e.g., at least two additional routing tiers) including fifth routing structures 655 may be formed over the fourth routing structures 663; and pad structures 657 may be formed over the fifth routing structures 655. In addition, fourth contact structures 659 may be formed to couple different fifth routing structures 655 with one another, different fourth routing structures 663, and/or different pad structures 657, as desired. Some of the fifth routing structures 655 may be coupled to some of the fourth routing structures 663 by way of some of the fourth contact structures 659; some of the fifth routing structures 655 may be coupled to some other of the fifth routing structures 655 by way of some other of the fourth contact structures 659; and some of the fifth routing structures 655 may be coupled to some of the pad structures 657 by way of yet still other of the fourth contact structures 659. The fifth routing structures 655, the pad structures 657, and the fourth contact structures 659 may respectively be formed of and include conductive material. In some embodiments, the fifth routing structures 655, the pad structures 657, and the fourth contact structures 659 are individually formed of and include one or more of W, Cu, Al, Ru, Mo, and TiN_{y}.

Still referring to FIG. 6, a fifth insulative material 661 may be formed on or over portions of at least the second insulative material 482 (FIG. 5B), the fourth routing structures 663, the second contact structures 665, the third contact structures 653, the fifth routing structures 655, the pad structures 657, and the fourth contact structures 659. In some embodiments, the fifth insulative material 661 is formed of and includes a dielectric oxide material, such as SiOₓ (e.g., SiO₂). The fifth insulative material 661 may be substantially homogeneous, or the fifth insulative material 661 may be heterogeneous. In some embodiments, an upper surface of the fifth insulative material 661 is formed to be substantially coplanar with upper surfaces of the pad structures 657. In additional embodiments, the upper surface of the fifth insulative material 661 is formed to vertically overlie the upper surfaces of the pad structures 657. In such embodiments, openings may be formed within the fifth insulative material 661 to at least partially expose (and, hence, facilitate access to) the upper surfaces of the pad structures 657.

As shown in FIG. 6, the method described above with reference to FIGS. 1A through 6 may effectuate the formation of a microelectronic device 651 (e.g., a memory device, such as a DRAM device) including the features (e.g., regions, structures, materials, devices) previously described herein. The microelectronic device 651 includes the memory array structure 100; the additional memory array structure 200 vertically overlying and attached to the memory array structure 100 in a F2F arrangement of the additional memory array structure 200 and the memory array structure 100; and the control circuitry structure 448 vertically overlying and attached to the additional memory array structure 200 in a B2B arrangement of the control circuitry structure 448 and the additional memory array structure 200. The microelectronic device 651 also includes the second contact structures 665, the third contact structures 653, the fourth routing structures 663, and the BEOL structures (e.g., the fifth routing structures 655, the pad structures 657, the fourth contact structures 659). At least some of the pad structures 657, at least some of the fifth routing structures 655, and at least some of the fourth contact structures 659 may be employed as global routing and interconnect structures for the microelectronic device 651 to, for example, receive global signals from an external bus, and to relay the global signals to other components (e.g., structures, devices) of the microelectronic device 651.

The configuration of the microelectronic device 651 may facilitate enhanced device performance (e.g., speed, data transfer rates, power consumption) relative to conventional microelectronic device configurations. For example, the configurations and positions of the anchor contact structures 244 of the additional memory array structure 200 may facilitate enhanced array efficiency for both the additional memory array structure 200 and the memory array structure 100, and may also control stresses while attaching (e.g., bonding) the second assembly 490 (including the control circuitry structure 448 thereof) to the first assembly 301 as well as during material thinning processes performed on the control circuitry structure 448 (e.g., facilitating relatively reduced vertical dimensions of the further semiconductor material 458). Furthermore, the F2F attachment of the additional memory array structure 200 to the memory array structure 100, and the B2B attachment of the control circuitry structure 448 to the additional memory array structure 200, may provide enhanced alignment margin as compared to conventional methods. Moreover, the method described above with reference to FIGS. 1A through 6 may resolve limitations on array (e.g., memory cell array) configurations, control logic device configurations, and associated device performance that may otherwise result from thermal budget constraints imposed by the formation and/or processing of arrays (e.g., memory cell arrays) of a microelectronic device.

Thus, in accordance with embodiments of the disclosure, a microelectronic device includes a memory array structure, an additional memory array structure vertically overlying and attached to the memory array structure, and a control circuitry structure vertically overlying and attached to the additional memory array structure. The memory array structure includes an array region having memory cells within a horizontal area thereof. The additional memory array structure includes an additional array region having additional memory cells within an additional horizontal area thereof. The additional array region horizontally overlaps the array region of the memory array structure. The control circuitry structure includes a control circuitry region horizontally overlapping each of the array region of the memory array structure and the additional array region of the additional memory array structure and having control logic devices within a further horizontal area thereof. At least some of the control logic devices are coupled to the memory cells of the memory array structure and the additional memory cells of the additional memory array structure. Channels of transistors of the control logic devices are positioned vertically closer to the additional memory cells than are gates of the transistors.

Furthermore, in accordance with embodiments of the disclosure, a method of forming a microelectronic device includes forming a memory array structure including an array region having memory cells within a horizontal area thereof. The memory cells respectively include an access device and a capacitor vertically overlying and coupled to the access device. An additional memory array structure is formed to include an additional array region having additional memory cells within an additional horizontal area thereof. The additional memory cells respectively include an additional access device and an additional capacitor vertically overlying and coupled to the additional access device. The additional memory array structure is attached to the memory array structure to form a first assembly. A control circuitry structure is formed to include control logic devices. The control circuitry structure is attached to the first assembly such that at least some of the control logic devices of the control circuitry structure are within the horizontal area of the array region of the memory array structure and the additional horizontal area of the additional array region of the additional memory array structure, and such that channels of transistors of the control logic devices are positioned vertically closer to the additional memory cells than are gate electrodes of the transistors.

Moreover, in accordance with embodiments of the disclosure, a memory device includes a memory array structure, an additional memory array structure, and a control circuitry structure. The memory array structure includes an array region having dynamic random-access memory (DRAM) cells therein. The DRAM cells respectively include an access device and a capacitor vertically overlying and coupled to the access device. The additional memory array structure overlies and is attached to the memory array structure and includes an additional array region having additional DRAM cells therein. The additional DRAM cells respectively include an additional access device and an additional capacitor vertically underlying and coupled to the additional access device. The control circuitry structure vertically overlies and is attached to the additional memory array structure. The control circuitry structure includes control logic devices within a control circuitry region horizontally overlapping the array region of the memory array structure and the additional array region of the additional memory array structure. Channels of transistors of the control logic devices are positioned vertically closer to the additional memory cells than are gate electrodes of the transistors.

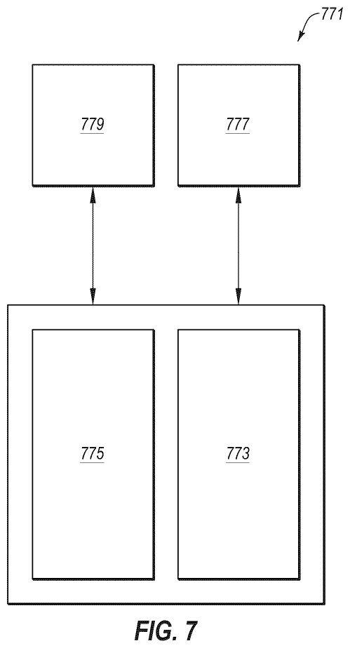

Microelectronic devices (e.g., the microelectronic device 651 (FIG. 6)) in accordance with embodiments of the disclosure may be used in embodiments of electronic systems of the disclosure. For example, FIG. 7 is a block diagram illustrating an electronic system 771 according to embodiments of disclosure. The electronic system 771 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 771 includes at least one memory device 773. The memory device 773 may comprise, for example, a microelectronic device (e.g., the microelectronic device 651 (FIG. 6)) previously described herein. The electronic system 771 may further include at least one electronic signal processor device 775 (often referred to as a “microprocessor”). The electronic signal processor device 775 may, optionally, comprise a microelectronic device (e.g., the microelectronic device 651 (FIG. 6)) previously described herein. While the memory device 773 and the electronic signal processor device 775 are depicted as two (2) separate devices in FIG. 7, in additional embodiments, a single (e.g., only one) memory/processor device having the functionalities of the memory device 773 and the electronic signal processor device 775 is included in the electronic system 771. In such embodiments, the memory/processor device may include a microelectronic device (e.g., the microelectronic device 651 (FIG. 6)) previously described herein. The electronic system 771 may further include one or more input devices 777 for inputting information into the electronic system 771 by a user, such as, for example, a mouse or other pointing device, a keyboard, a touchpad, a button, or a control panel. The electronic system 771 may further include one or more output devices 779 for outputting information (e.g., visual or audio output) to a user such as, for example, a monitor, a display, a printer, an audio output jack, a speaker, etc. In some embodiments, the input device 777 and the output device 779 comprise a single touchscreen device that can be used both to input information to the electronic system 771 and to output visual information to a user. The input device 777 and the output device 779 may communicate electrically with one or more of the memory device 773 and the electronic signal processor device 775.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
a memory array structure comprising an array region having memory cells within a horizontal area thereof;
an additional memory array structure vertically overlying and attached to the memory array structure, the additional memory array structure comprising:
an additional array region having additional memory cells within an additional horizontal area thereof, the additional array region horizontally overlapping the array region of the memory array structure; and
a control circuitry structure vertically overlying and attached to the additional memory array structure, the control circuitry structure comprising:
a control circuitry region horizontally overlapping each of the array region of the memory array structure and the additional array region of the additional memory array structure and having control logic devices within a further horizontal area thereof,
at least some of the control logic devices coupled to the memory cells of the memory array structure and the additional memory cells of the additional memory array structure, and
channels of transistors of the control logic devices positioned vertically closer to the additional memory cells than are gates of the transistors.

2. The microelectronic device of claim 1, wherein the additional memory array structure is attached to the memory array structure through a combination of oxide-to-oxide bonds and metal-to-metal bonds.

3. The microelectronic device of claim 2, wherein the control circuitry structure is attached to the additional memory array structure through additional oxide-to-oxide bonds.

4. The microelectronic device of claim 1, wherein the additional memory cells of the additional memory array structure are vertically inverted relative to the memory cells of the memory array structure.

5. The microelectronic device of claim 1, wherein memory array structure further comprises:
semiconductor material partially vertically underlying the memory cells; and
isolation structures vertically extending partially through the semiconductor material, at least some of the isolation structures defining boundaries of active regions of the semiconductor material defining access transistors of the memory cells.

6. The microelectronic device of claim 5, wherein the memory array structure further comprises:
a digit line exit region horizontally neighboring the array region in a first direction and comprising digit line contact structures coupled to digit lines in operable communication with access transistors of the memory cells; and
a word line exit region horizontally neighboring the array region in a second direction orthogonal to the first direction, the word line exit region comprising word line contact structures coupled to word lines in operable communication with the access transistors of the memory cells.

7. The microelectronic device of claim 6, wherein the additional memory array structure further comprises:
additional semiconductor material partially vertically overlying the additional memory cells;
additional isolation structures vertically extending completely through the additional semiconductor material, at least some of the additional isolation structures defining boundaries of additional active regions of the additional semiconductor material defining additional access transistors of the additional memory cells; and
anchor contact structures within horizontal areas of and vertically extending partially through at least some of the additional isolation structures, at least some of the anchor contact structures coupled to at least some of the control logic devices.

8. The microelectronic device of claim 7, further comprising:
an additional digit line exit region horizontally neighboring the additional array region in the first direction and horizontally overlapping the digit line exit region of the memory array structure, the additional digit line exit region comprising:
first additional digit line contact structures coupled to additional digit lines in operable communication with additional access transistors of the additional memory cells; and
second additional digit line contact structures coupled to the digit line contact structures of the memory array structure; and
an additional word line exit region horizontally neighboring the additional array region in the second direction and horizontally overlapping the word line exit region of the memory array structure, the additional word line exit region comprising:
first additional word line contact structures coupled to additional word lines in operable communication with the additional access transistors of the additional memory cells; and
second additional word line contact structures coupled to the word line contact structures of the memory array structure.

9. The microelectronic device of claim 1, further comprising:
routing structures vertically interposed between and coupled to the additional memory cells of the additional memory array structure and the control logic devices of the control circuitry structure; and
additional routing structures vertically overlying the control circuitry structure, some of the additional routing structures coupled to the control logic devices of the control circuitry structure.

10. The microelectronic device of claim 9, further comprising contact structures respectively vertically extending from some of the additional routing structures to some of the routing structures.

11. A method of forming a microelectronic device, comprising:
forming a memory array structure including an array region having memory cells within a horizontal area thereof, the memory cells respectively comprising an access device and a capacitor vertically overlying and coupled to the access device;
forming an additional memory array structure including an additional array region having additional memory cells within an additional horizontal area thereof, the additional memory cells respectively comprising an additional access device and an additional capacitor vertically overlying and coupled to the additional access device;
attaching the additional memory array structure to the memory array structure to form a first assembly;
forming a control circuitry structure comprising control logic devices; and
attaching the control circuitry structure to the first assembly such that:
at least some of the control logic devices of the control circuitry structure are within the horizontal area of the array region of the memory array structure and the additional horizontal area of the additional array region of the additional memory array structure; and
channels of transistors of the control logic devices are positioned vertically closer to the additional memory cells than are gate electrodes of the transistors.

12. The method of claim 11, wherein attaching the additional memory array structure to the memory array structure comprises:
vertically inverting the additional memory array structure; and
bonding the additional memory array structure to the memory array structure through a combination of oxide-to-oxide bonding and metal-to-metal bonding after vertically inverting the additional memory array structure.

13. The method of claim 12, wherein attaching the control circuitry structure to the first assembly comprises bonding the control circuitry structure over the additional memory array structure through oxide-to-oxide bonding.

14. The method of claim 13, further comprising forming conductive contacts vertically extending through the control circuitry structure and coupled to:
the control logic devices of the control circuitry structure;
the additional memory cells of the additional memory array structure; and
the memory cells of the memory array structure.

15. The method of claim 14, further comprising:
forming conductive routing structures vertically over and coupled to at least some of the conductive contacts; and
forming conductive pad structures vertically over and coupled to at least some of the conductive routing structures.

16. The method of claim 11, further comprising forming the additional memory array structure to further comprise:
semiconductor material partially vertically overlying the additional memory cells;
isolation structures vertically extending through the semiconductor material, at least some of the isolation structures defining boundaries of active regions of the semiconductor material defining access transistors of the additional memory cells; and
anchor contact structures within horizontal areas of and vertically extending partially through at least some of the isolation structures, at least some of the anchor contact structures coupled to at least some of the control logic devices.

17. A memory device, comprising:
a memory array structure including an array region having dynamic random-access memory (DRAM) cells therein, the DRAM cells respectively comprising an access device and a capacitor vertically overlying and coupled to the access device;
an additional memory array structure overlying and attached to the memory array structure and including an additional array region having additional DRAM cells therein, the additional DRAM cells respectively comprising an additional access device and an additional capacitor vertically underlying and coupled to the additional access device; and
a control circuitry structure vertically overlying and attached to the additional memory array structure, the control circuitry structure comprising:
control logic devices within a control circuitry region horizontally overlapping the array region of the memory array structure and the additional array region of the additional memory array structure, channels of transistors of the control logic devices positioned vertically closer to the additional DRAM cells than are gate electrodes of the channels of transistors.

18. The memory device of claim 17, further comprising back-end-of-line (BEOL) structures vertically overlying and coupled to the control logic devices of the control circuitry structure, the BEOL structures comprising:
conductive routing structures vertically overlying and coupled to at least some of the control logic devices; and
conductive pad structures vertically overlying and coupled to at least some of the conductive routing structures.

19. The memory device of claim 17, wherein the additional memory array structure further comprises anchor contact structures within horizontal areas of and vertically extending partially through isolation structures vertically extending completely through semiconductor material of the additional memory array structure.

20. The memory device of claim 19, further comprising routing structures vertically interposed between the control logic devices of the control circuitry structure and the additional DRAM cells of the additional memory array structure, the routing structures coupled to the anchor contact structures.
